(19) United States
(12) Patent Application Publication
(10) Pub. No.: US 2014/0008119 A1
(43) Pub. Date: Jan. 9, 2014

(54) APPARATUSES, SYSTEMS, AND METHODS FOR ELECTROMAGNETIC PROTECTION

(71) Applicant: Kurt Robert Brandt, Hubertus, WI (US)

(72) Inventor: Kurt Robert Brandt, Hubertus, WI (US)

(73) Assignee: BRANDT INNOVATIVE TECHNOLOGIES, INC., Pewaukee, WI (US)

(21) Appl. No.: 13/876,353

(22) PCT Filed: Sep. 29, 2011
(86) PCT No.: PCT/US11/54095

§ 371 Date: Sep. 9, 2013

Related U.S. Application Data
(60) Provisional application No. 61/387,525, filed on Sep. 29, 2010.

(51) Int. Cl. H05K 9/00

(52) U.S. Cl. CPC H05K 9/0007
USPC 174/382

(57) ABSTRACT

Systems, apparatuses, and methods are provided for protecting electronic devices from electromagnetic threats. Exemplary systems, apparatuses, and methods may include utilizing meta-material, wire grids including specially coated fibers, carrying cases including electromagnetic protective liners or inserts, enclosures for containing electronic devices and protecting such devices from electromagnetic threats, connection members for connecting panels of an enclosure, soft-sided enclosures such as tents or rooms for protecting electronic devices contained therein, low-profile meta-material gaskets for electromagnetically protection openings in an enclosure, among other things.

### RELATED APPLICATIONS

The present application claims the benefit of U.S. Provisional Patent Application No. 61/387,525, filed Sep. 29, 2010, the entire content of which is hereby incorporated herein by reference.

### FIELD OF THE INVENTION

The present invention generally relates to electro-magnetic protection and generation and, more particularly, to apparatuses, systems, and methods for electro-magnetic protection and generation.

### BACKGROUND

Sophisticated electronics are a critical component of communication, power, transportation, industrial, financial, medical, food, government and emergency services, among others, that make up much of our civilian infrastructure. Additionally, the military continues to leverage more and more sophisticated modern electronic technologies for communication, weapons systems, sensor and autonomous vehicles. These electronics system can be disrupted or destroyed by a variety of electromagnetic threats (ET). These threats manifest themselves as an electromagnetic pulse (EMP), high power microwaves (HPM), lightning, electromagnetic interference (EMI), radio frequency interference (RFI), among others. Origins of these threats are many such as, for example, from a high-altitude nuclear detonation, solar flare activity, a military EMP/HPM weapon, an improvised EMP/HPM weapon, etc. Some devices purport to be protected from EMI utilizing one of many standards (e.g., MIL STD) and fewer yet purport to be protected from EMP (e.g., MIL STD 188 125 etc.). However, most electronic devices remain unprotected.

Some methods that purport to control electromagnetic (EM) radiation involve high conductivity and/or permittivity shielding, EM-absorbing materials and structured materials. More recently, conductive polymer nanostructures and new classes of structured materials referred to as meta-materials have been the focus of EMI and ERFI shielding research.

With reference to FIGS. 1 and 2, existing metallic enclosures purport to offer a broadband solution to EM shielding. However, most metallic enclosures suffer from poor shielding characteristics at lower frequencies and allow magnetic field radiation to enter the enclosure. Such enclosures are also susceptible to RF leakage due to aperture opening at high frequencies.

Carefully sealed metallic or metallically coated enclosures may provide some broadband shielding, but the shielding effectiveness falls off at low frequencies as the skin depth becomes large compared to the thickness of the shielding material. In addition, at higher frequencies, small openings in metallic enclosures become aperture antennas, which decrease the shielding effectiveness dramatically.

With reference to FIGS. 3-7, some commercial EM Absorbers are in the market and may offer only a small absorption over a broad spectral range with improved absorption in a narrow band range.

With reference to FIGS. 8-11, recent advances in advanced materials may offer a possibility of negative index of refraction parameters, but are currently restricted in regards to angle of incidence, useful bandwidth, restrictive geometries, and non optimized form-factors for manufacturing or real-world applications.

The United States military is one of the most modern in the world, and one of the most technologically advanced in its command & control structure. It has prided itself on being able to dismantle and disable command and control systems of its adversaries using EMP/HERF (e.g., both Gulf wars in Iraq). However, because of the pervasive nature of the electrical, digital and computerized command and control system of the United States military, the United States military is also extremely vulnerable to an electromagnetic warfare attack by a capable national entity, a rogue nation, or a local terrorist group with an EMP weapon or other comparable device. RF radiation is pervasive in the war fighter's environment with all manner of electrical communication on multiple frequencies and operating where jamming, radar and other electronic warfare elements are present.

Due to the signal distortion introduced by EM threats, EM can cause data loss within and about a network component exhibiting the same, and can interfere with or otherwise adversely affect the other electronic devices adjacent thereto.

A nuclear detonation far above the earth's surface, for example at 25 miles above sea level, produces an electromagnetic field known as a high altitude electromagnetic pulse (HEMP). Additionally, a Coronal Mass Ejection (CME) from the sun can release high-energy particles that may interact with the earth's atmosphere to produce HEMP. Such pulses or energy spikes can cause damage and failure to power systems, telephone networks, electronic devices, and computers across a large geographical area. Systems connected to power lines and telephone wires are particularly vulnerable to the current and voltage surges resulting from an electromagnetic pulse.

A multitude of man-made directed energy weapons exist, or are in development, that are capable of creating Electro-Magnetic Pulses (EMP). Such pulses or energy spikes can cause damage and failure to power systems, telephone networks, electronic devices, and computers in well-targeted areas.

Many devices feature protection from electronic surges originating from lightning. However, EMP can involve pulses that are shorter in duration and represent higher peak amplitudes than is provided from in standard EMI and static protection devices. Current shielding technologies require careful handling to maintain electrical shielding characteristics.

It is known in the art that a facility shield against EMP/IEMI events can be constructed making a solid electromagnetically conductive enclosure (sometimes called a “Faraday cage”). These enclosures lack practical applicability in certain applications; however, as any attempt to access the interior of the enclosure disrupts the shielding effect and exposes any sensitive equipment housed in the enclosure to a timely EMP/IEMI event. Existing and planned data centers using such enclosures tend to be individually engineered in that the physical layout of the spaces is different from data center to data center. This type of approach may lead to high design and construction costs. Moreover, existing methods for protecting sensitive electronics from electromagnetic interference are designed with a narrow range of applicability in mind and does not cover the entire range of potential EMP/IEMI threats.

The use of highly developed electronics has provided the world with many applications that are integral to operation of financial, medical, electric-utility, and many other industries. The use of electronics is also integral to the operation of supporting infrastructure items such as the power grid, air conditioning, and emergency electricity-generation equipment, provision of fresh water, food production and storage, waste management, medical supplies, and all areas of modern infrastructure. Large-scale data centers typically used to perform operations in a number of industries are not currently designed with these concerns in mind, and are constructed in such a way to make modifications, whether for protection, expansion, or other reasons, extremely difficult.

The disclosed apparatuses, systems, and methods including material, panels, connecting panels together, doors, windows and other parts of electromagnetic protection enclosures provide an improvement regarding vulnerability to manufacturing defects, improper handling, higher performance, among other things, and make the workflow more amenable to the ease of use on unprotected enclosures.

In addition, the disclosed apparatuses, systems, and methods including enclosures provide a comprehensive protection solution against EMP threats in regards to radiated EMP, EMP conducted through power, EMP conducted through communications, and EMP conducted through environmental controls.

Thus, a need exists, in many environments and in many applications, to provide protection against electromagnetic threats, whether such threats occur naturally or are man-made.

### SUMMARY

In one example, apparatuses, systems, and methods are provided to cure one or more of the deficiencies identified above.

In another example, apparatuses, systems, and methods are provided to provide protection against electromagnetic threats.

In a further example, apparatuses, systems, and methods are provided to protect rack-mounted electronics from electromagnetic interference (EMI).

In yet another example, apparatuses, systems, and methods are provided to protect computer network equipment from EMI.

In yet a further example, apparatuses, systems, and methods are provided to protect industrial control electronics from EMI.

In still another example, apparatuses, systems, and methods are provided to protect transportation control electronics from EMI.

In still a further example, apparatuses, systems, and methods are provided to protect test instrumentation from EMI.

In another example, apparatuses, systems, and methods are provided to protect mobile radio devices from EMI.

In a further example, apparatuses, systems, and methods are provided to protect high voltage power supplies from EMI.

In yet another example, apparatuses, systems, and methods are provided to protect command and control equipment from EMI.

In yet a further example, apparatuses, systems, and methods are provided to protect items under test from EMI.

In still another example, apparatuses, systems, and methods are provided to generate Electromagnetic Pulse (EMP).

A commercial need exists and may include a cost-effective way to protect the critical infrastructure of business and government that includes server systems, personal computers, and wireless devices. EMI/RFI tents may be an important emergency preparedness item for US Homeland Security to accommodate such activities as, but not limited to, medical operations, command and control, and other critical emergency operations. Technology used to develop EMI/RFI tents may also be used to provide soft-sided protection for portable electronics like laptop PCs, medical and test instrumentation, wireless devices, among other devices.

An enclosure may be made of welded steel components and assembled using EMI gasket material to produce an enclosure that shields the contents from damaging effects of externally impinging electromagnetic energy. This technique applied to modular electronics enclosures such as those used in data centers, rooms made from shipping containers, modular data center rooms, test systems, and even entire facilities. Furthermore, additional care may be taken to prevent electromagnetic energy from entering the enclosure through power connections, data connections, or environmental controls. Most typical EMI applications only provide 20 db of shielding effectiveness.

In another example, a new set of materials is provided that may replace metallic panels of an enclosure and a new method is provided to make connections between panels. The panels offer the additional feature of allowing visible light through the panels while still providing a shielding effectiveness that may be designed to exceed 100 db.

In a further example, these new materials may be put to use for protecting aircraft, enclosures, displays, and imagers from electromagnetic energy.

Conventional enclosures utilize traditional EMI gaskets to fill any gaps in said enclosures and merely provide about 20 db of shielding effectiveness. The use of EMI gaskets is costly and requires care in manufacturing and use. It is well understood that the gaps between conducting panels of an enclosure act as “antennas” and transmit energy between the inside and outside of an enclosure. When used on doors and access panels special care is required to maintain contact between panels. The present invention includes apparatuses, systems, and methods to protect electronic devices from radiation that “leaks” through the connections between shielded panels. For example, at least two new methods to provide EMI/EMP shielding without the use of traditional EMI gaskets arc provided. In some examples, geometric structures that act like antennas are replaced with structures that act like wave guides. Wave guides may be designed to attenuate a range of frequencies to levels exceeding 100 db.

The present invention also removes the requirement that contact between adjacent panels be maintained at all times using traditional EMI gaskets. This advantage reduces effort, costs, and potential for failure as compared to traditional EMI gaskets.

In another example, apparatuses, systems, and methods utilizing the shielding methodology of the present invention are provided to electromagnetically-protected cable-management systems.

In a further example, an apparatus is provided utilizing the shielding methodology of the present invention for electromagnetically isolating electronics devices from surrounding environment in order to prevent a transfer of electrical and magnetic field energy between the electronics devices and the environment utilizing specialized geometric arrangements of materials comprising enclosure walls, connection between walls, electronic penetrations into the enclosure, and non-electric penetrations into enclosure.

The apparatus of the prior example may utilize individual or combined examples of electromagnetically protected panels.

The apparatus of the prior example may utilize individual or combined examples of electromagnetically protected connections between panels.

The apparatus of the prior example may utilize individual or combined examples of electromagnetically protected cable management systems.

In still other examples, a wall is provided and may be comprised of a composite of dielectric interposed by a patterned array of conductive materials that together act as broad-band electromagnetically-resonant attenuator.

In the prior example, the patterned array may be comprised of waveguides whose length and width proportions are greater than four (4) such that the attenuation of greater than 100 dB below a specific wavelength given by 2 times the width.

In the prior example, the dielectric may be air.

In still further examples, mating between enclosure components is provided and may be comprised of a composite of dielectric interposed by a patterned array of conductive materials that together act as broad-band electromagnetically-resonant attenuator.

In the prior example, the patterned array may be comprised of waveguides whose length and width proportions are greater than four (4) such that the attenuation below a specific wavelength given by 2 times the width is 100 dB or greater.

In the prior example, the dielectric may be air.

In yet another example, a wall is provided and may be comprised of a composite of dielectric interposed by a patterned array of conductive materials that together serves to give a material thickness that is large compared to the skin depth.

In yet a further example, walls are provided and may be geometrically arranged to provide attenuated electric field or attenuated magnetic field or both attenuated electric field and attenuated magnetic field, due to the response of an external field, according to the rules of Maxell's equations.

In another example, mating between wall sections are provided and may be geometrically arranged to provide either attenuated electric field or attenuated magnetic field or both attenuated electric field and attenuated magnetic field, due to the response of an external field, according to the rules of Maxell's equations.

In the prior example, the mating between walls may be geometrically arranged to and the geometric arrangement could form an inside corner.

In a further example, an electromagnetic lens is provided and may be used to map desired wall geometry into one that is geometrically arranged to provide either attenuated electric field or attenuated magnetic field or both attenuated electric field and attenuated magnetic field, due to the response of an external field, according to the rules of Maxell's equations.

In still another example, an electromagnetic lens is provided and may be used to map desired wall mating geometry into one that is geometrically arranged to provide either attenuated electric field or attenuated magnetic field or both attenuated electric field and attenuated magnetic field, due to the response of an external field, according to the rules of Maxell's equations.

In still a further example, an electromagnetic lens is provided and may be comprised of a passive arrangement of dielectric and/or conductive materials that remap the electric and/or magnetic field lines to provide either attenuated electric field or attenuated magnetic field or both attenuated electric field and attenuated magnetic field.

In yet another example, an enclosure is provided and may contain provisions for mounting standard data center components therein such as computers, storage devices, and communications equipment

In yet a further example, an enclosure is provided and may contain doors and access panels that are geometrically arranged to provide attenuated electric field or attenuated magnetic field or both attenuated electric field and attenuated magnetic field, due to the response of an external field, according to the rules of Maxell's equations.

In another example, an enclosure is provided and may contain doors and access panels including mating components, which may be comprised of a composite of dielectric interposed by a patterned array of conductive materials that together act as broad-band electromagnetically-resonant attenuator.

In a further example, an enclosure is provided and may contain a management system for non-conductive cables, where the cable management system consist of dielectric and conductors that are geometrically arranged to provide attenuated electric field or attenuated magnetic field or both attenuated electric field and attenuated magnetic field, due to the response of an external field, according to the rules of Maxell's equations.

In still another example, an enclosure is provided and may contain a management system for non-conductive cables, where the cable management system consist of dielectric and conductors that are geometrically arranged and comprised of a composite of dielectric interposed by a patterned array of conductive materials that together act as broad-band electromagnetically-resonant attenuator.

In still a further example, apparatuses, systems, and methods for protecting rack-mounted electronics from EMI are provided.

In yet another example, apparatuses, systems, and methods for protecting computer network equipment from EMI are provided.

In yet a further example, apparatuses, systems, and methods for protecting industrial control electronics from EMI are provided.

In another example, apparatuses, systems, and methods for protecting transportation control electronics from EMI are provided.

In a further example, apparatuses, systems, and methods for protecting test instrumentation from EMI are provided.

In still another example, apparatuses, systems, and methods for protecting mobile radio devices from EMI are provided.

In still a further example, apparatuses, systems, and methods for protecting high voltage power supplies from EMI are provided.

In yet another example, apparatuses, systems, and methods for protecting command and control equipment from EMI are provided.

In yet a further example, apparatuses, systems, and methods for protecting medical electronics from EMI are provided.

In another example, apparatuses, systems, and methods for protecting aircraft from EMI are provided.

In a further example, apparatuses, systems, and methods for protecting military vehicles from EMI are provided.

In still another example, apparatuses, systems, and methods for protecting emergency vehicles from EMI are provided.

### BRIEF DESCRIPTION OF THE DRAWINGS

FIG. 1 is a front view of a conventional enclosure for containing electronic devices;

FIG. 2 is a chart of an exemplary standard for shielding effectiveness, specifically this standard is MIL-HDBK-1195;

FIG. 3 is a front view of a conventional electromagnetic absorber;

FIG. 4 is an chart demonstrating reflection loss (dB) versus thickness to illustrate deficiencies of conventional electromagnetic absorbers;

FIG. 5 is a chart demonstrating reflection attenuation versus frequency to illustrate deficiencies of conventional electromagnetic absorbers;

FIG. 6 is a top perspective view of a prior art electromagnetic absorber;

FIG. 7 is a top perspective view of a prior art electromagnetic absorber;

FIG. 8 is a 2D illustration demonstrating shielding of an object without using a conductive enclosure;

FIG. 9 is a 3D illustration demonstrating shielding of an object without using a conductive enclosure;

FIG. 10 is a chart demonstrating deficient performance of the material shown in FIG. 11 well below desired levels of performance;

FIG. 11 is a top perspective view of a material that provides shielding characteristics well below desired level;

FIG. 12 is chart illustrating a plurality of exemplary applications in which the present invention may be used;

FIG. 13 is a top perspective view of a portion of an exemplary wire grid;

FIG. 14 is a cross-sectional view of an exemplary wire of a wire grid;

FIG. 15 is a cross-sectional view of another exemplary wire of a wire grid;

FIG. 16 is a cross-sectional view of a further exemplary wire of a wire grid;

FIG. 17 is a cross-sectional view of yet another exemplary wire of a wire grid;

FIG. 18 is a cross-sectional view of an exemplary composite panel;

FIG. 19 is a cross-sectional view of a portion of an exemplary carrying case;

FIG. 20 is a cross-sectional view of a portion of another exemplary carrying case;

FIG. 21 is an internal elevation view of an exemplary enclosure that provides protection against EMI;

FIG. 22 is a top perspective view of another exemplary embodiment of an enclosure that protects against EMI;

FIG. 23 is a top perspective view of a portion of a conventional enclosure that does not include physical characteristics for protecting against EMI/EMP;

FIG. 24 is a cross-sectional view of an exemplary connection between a composite shielding panel and an enclosure frame;

FIG. 25 is a block diagram of an exemplary integrated battery backup system and thermal control system;

FIG. 26 is a block diagram of an exemplary system for harvesting electrical energy from a PC Microprocessor with an external Liquid-based heat exchanger;

FIG. 27 is a block diagram of an exemplary system for harvesting electrical energy from a PC microprocessor with external air-based heat exchanger;

FIG. 28 is a top perspective view of an exemplary system for liquid-based thermal management and energy harvesting system for direct cooling of electronic components;

FIG. 29 is a top perspective of a portion of an exemplary PCI bulkhead;

FIG. 30 is a top perspective view of an exemplary soft sided protective enclosure;

FIG. 31 is a cross-sectional view taken along line 31-31 of FIG. 30;

FIG. 32 is an exploded view of a portion of an exemplary multi-layered soft sided enclosure;

FIG. 33 is a cross-sectional view of a portion of another exemplary multi-layered soft sided enclosure;

FIG. 34 is a top perspective view of a further exemplary soft sided enclosure;

FIG. 35 is a cross-sectional view of an exemplary manner of physically bonding a joint of a soft sided enclosure;

FIG. 36 is a diagram illustrating a conductor placed in an electric field, this illustration also illustrates that a good conductor charge is free to redistribute in order to provide a zero electric filed inside a conductor, and this property is used to shield the contents from affects of external electric fields, plane magnetic waves induce current on good conductors that rearrange currents and allow good conductors to shield against magnetic waves;

FIG. 37 is an diagram illustrating that non-plane waves are not effectively shielded by conductors and must be shielded with a magnetic material;

FIG. 38 is a chart illustrating that the effectiveness with which a material will shield the electric field depends on both the conductivity and frequency;

FIG. 39 is a cross-sectional view of an exemplary Fiber of an exemplary high performance material;

FIG. 40 is a top perspective view of an exemplary soft sided structure that requires electromagnetic protection;

FIG. 41 is a cross-sectional view of an exemplary multi-wall fabric;

FIG. 42 is a cross-sectional view of an exemplary wall to wall seam;

FIG. 43 is a cross-sectional view of an exemplary wall to floor seam;

FIG. 44 is a cross-sectional view of an exemplary door system for providing electromagnetic protection;

FIG. 45 includes illustrations relating to the behavior of an electric field near a dielectric;

FIG. 46 is an illustration relating to the behavior of a magnetic field near an opening in a structure;

FIG. 47 is an illustration relating to the behavior of an electric field near an opening in a structure;

FIG. 48 is an exemplary waveguide feed-through used in connection with openings in enclosures;

FIG. 49 includes a plurality of illustrations containing materials having different properties and their result effect on surrounding magnetic field;

FIG. 50 is a cross-sectional view of an exemplary arrangement of low-profile resonant structures surrounding an opening in an enclosure wall;

FIG. 51 is top view and a cross-sectional side view of an exemplary low-profile EMI material gasket;

FIG. 52 is a cross-sectional side view of another exemplary low-profile EMI material gasket;

FIG. 53 is a cross-sectional view of an exemplary device for protecting a wireless device from EMP while still allowing use of the device;

FIG. 54 is a schematic view of an exemplary antenna subsystem module associated with the device of FIG. 54;

FIG. 55 is a block diagram of an exemplary integrated EMP sensor of an exemplary integrated system monitor;

FIG. 56 is a module layout of another exemplary integrated EMP sensor of an exemplary integrated system monitor;

FIG. 57 is an illustration of an exemplary EMP sensor including an ultrawideband antenna and a electro optic crystal;

FIG. 58 is a top view and a side view of exemplary converters also referred to as a Grenouille;

FIG. 59 is a block diagram of an exemplary femtosecond pulse characterization device;

FIG. 60 is cross-sectional view of an exemplary electromagnetic protected industrial pushbutton system;

FIG. 61 is cross-sectional view of an exemplary electromagnetic protected industrial panel light system;

FIG. 62 is front view and a side view of an exemplary electromagnetic shielded panel with integrated sensor system;

FIG. 63 is schematic view of an exemplary protected narrow-band power transformer;

FIG. 64 is a plurality of schematic views of a plurality of resonator styles that may be assembled together to form advanced transformer cores;

FIG. 65 is an electrical schematic of an exemplary high voltage source;

FIG. 66 is a top perspective view of an exemplary storage enclosure;

FIG. 67 is a schematic view of an exemplary Ethernet system;

FIG. 68 is a perspective view of an exemplary cable system;

FIG. 69 is an end view of an exemplary shipping container;

FIG. 70 is an end view of another exemplary shipping container;

FIG. 71 is a top view of a portion of an exemplary EMP/EMI protected test room or enclosure;

FIG. 72 is a top view of a portion of an exemplary EMP/EMI protected test room or enclosure, the portion include a flat span of the enclosure;

FIG. 73 is a top view of a portion of an exemplary EMP/EMI protected test room or enclosure, the portion include a corner of the enclosure;

FIG. 74 is a top perspective view of an exemplary EMP/EMI protected test room or enclosure;

FIG. 75 is a top perspective view of a portion of an exemplary modular screened structure shown in FIG. 76;

FIG. 76 is a top perspective view of an exemplary modular screened structure;

FIG. 77 is a top perspective view of an exemplary air-operated switch that does not require submersion in transformer oil;

FIG. 78 is a top perspective view of a portion of the switch shown in FIG. 77;

FIG. 79 is a schematic view of an exemplary generator;

FIG. 80 is an exemplary physical layout of the generator shown in FIG. 79;

FIG. 81 is a perspective view of an exemplary composite shield or member;

FIG. 82 is chart illustrating a plurality of exemplary applications in which composite panels may be utilized;

FIG. 83 is a plurality of views illustrating gaps that may be provided when enclosure panels are mated together;

FIG. 84 is a plurality of views of EMI gaskets used to seal gaps between enclosure panels;

FIG. 85 is a graph representing electric and magnetic fields near the surface of a conductor;

FIG. 86 is a graph illustrating conditions of Maxwell's equations;

FIG. 87 is a top view of an exemplary enclosure having an inside corner at an outside corner of the enclosure, an exemplary electric field and gap between adjacent panels is also illustrated;

FIG. 88 is a top view of an enclosure not including an inside corner at an outside corner of the enclosure, an exemplary electric field and gap between adjacent panels is also illustrated;

FIG. 89 is a top perspective view of an exemplary embodiment of two structured components;

FIG. 90 is a view containing an exemplary embodiment of a rectangular waveguide and associated formulas for calculating the cut-off frequency;

FIG. 91 is an exemplary chart that represents attenuation versus frequency for TM and TEM modes in a waveguide which increase drastically below the cutoff frequency and illustrates the broadband nature of this type of EMI/EMP protection below the cutoff frequency;

FIG. 92 is a plurality of view of two exemplary structured components with the components meeting to form waveguides at an interface between the components;

FIG. 93 is a side view of two exemplary structured components that mate to form waveguides at an interface between the components;

FIG. 94 is a view of two exemplary structured components that mate to form waveguides at an interface between the components;

FIG. 95 is a view of two exemplary structured components that mate to form waveguides at an interface between the components;

FIG. 96 is a top perspective view of two exemplary structured components that mate to form waveguides at an interface between the components;

FIG. 97 is a top view of two exemplary structured components that mate to form waveguides at an interface between the components;

FIG. 98 is a top perspective view of an EMI/EMP protected cable management system that includes two mating structured components meeting to form waveguides at an interface between the components;

FIG. 99 is an exploded view of the cable management system shown in FIG. 98;

FIG. 100 is a top view of the cable management system shown in FIG. 98, a cable is also shown in this figure;

FIG. 101 is a top perspective view of an exemplary EMI/EMP protected cabinet or enclosure for containing electronic devices therein;

FIG. 102 an electrical schematic of an exemplary system for active protection and control;

FIG. 103 is an exploded view of another exemplary enclosure that provides EMI/EMP protection to electronic devices within the enclosure;

FIG. 104 is an exploded view of a further exemplary enclosure that provides protection against EMI/EMP;

FIG. 105 an internal elevation view of still another enclosure that provides protection against EMI/EMP; and

FIG. 106 is an exploded view of an exemplary room or enclosure that protects against EMI/EMP.

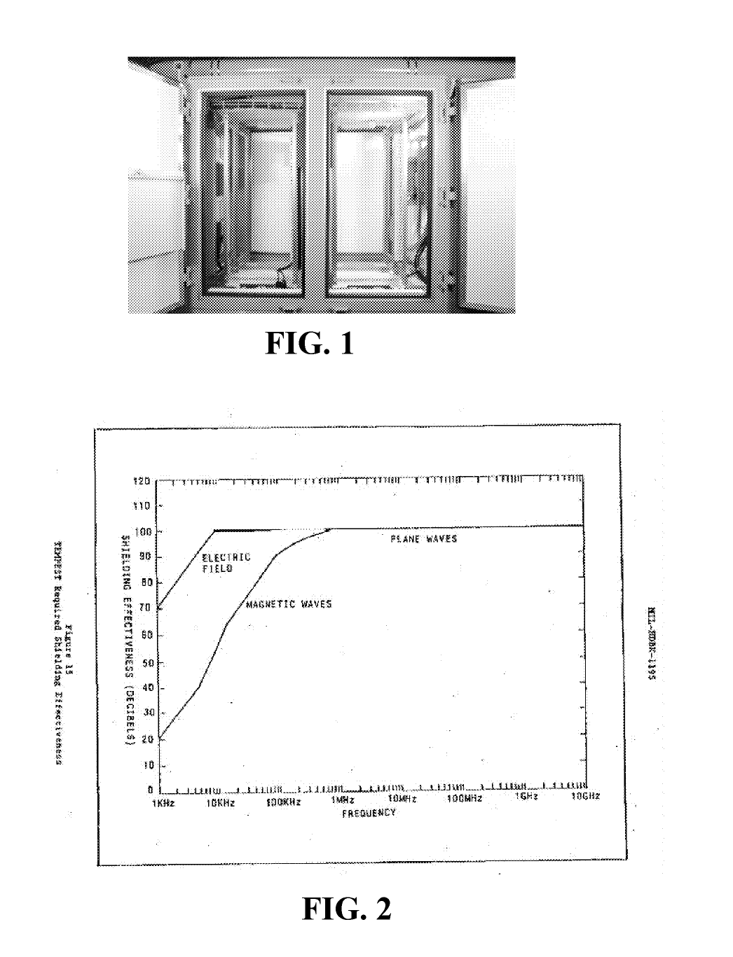

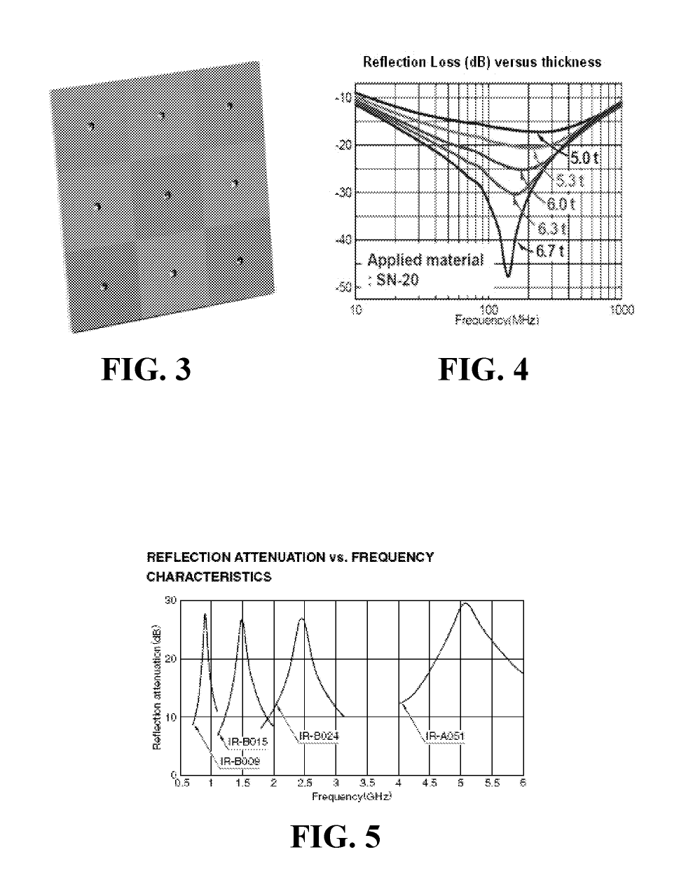

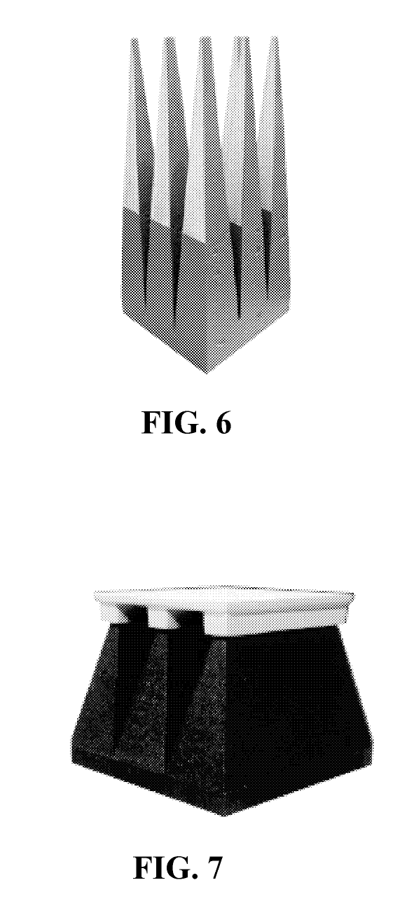

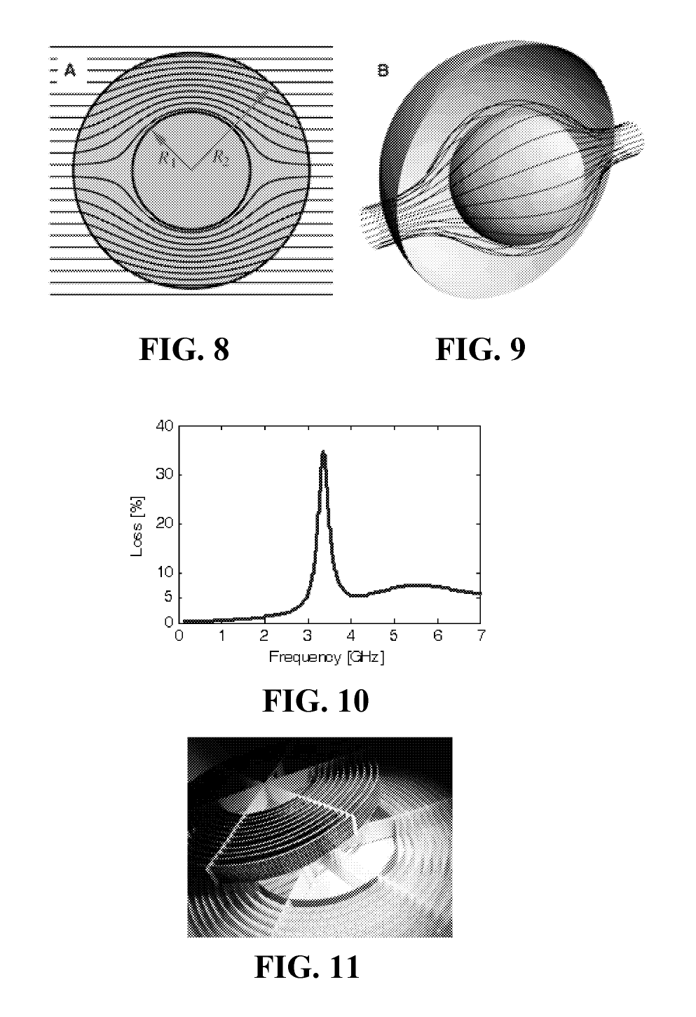

Before any independent features and embodiments of the invention are explained in detail, it is to be understood that the invention is not limited in its application to the details of the construction and the arrangement of the components set forth in the following description or illustrated in the drawings. The invention is capable of other embodiments and of being practiced or of being carried out in various ways. Also, it is understood that the phraseology and terminology used herein is for the purpose of description and should not be regarded as limiting.

### DETAILED DESCRIPTION

Systems, apparatuses, and methods of the present invention may be useable in a wide variety of applications to protect against electromagnetic (EM) threats. EM threats may be used to describe a variety of electromagnetic related threats including, but not limited to, Electro-Magnetic Pulse (EMP), High-altitude Electro-Magnetic Pulse (HEMP), Electro-Magnetic Interference (EMI), Intentional Electro-Magnetic Interference (IEMI), Electronic Warfare (EW), Electronic Jamming Devices and other Directed Energy Weapons.

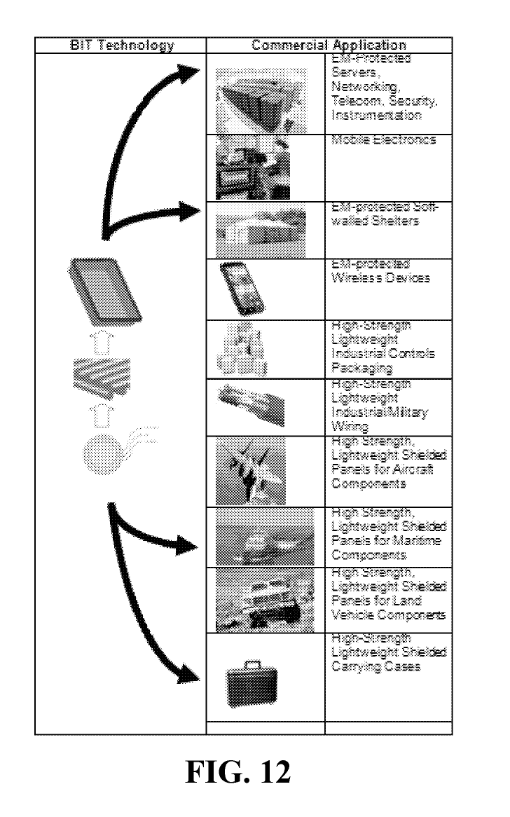

Some of the exemplary applications in which the systems, apparatuses, and methods of the present invention may be used are illustrated in FIG. 12. These applications are only exemplary and are not intended to be limiting. Rather, the systems, apparatuses, and methods of the present invention may be useable in a wide variety of additional applications. With continued reference to FIG. 12, some of the exemplary applications include network systems, server systems, telecom systems, security systems, electronic instrumentation, mobile electronics, soft walled structures/shelters, wireless devices, industrial controls packaging, industrial or military wiring, aircraft, maritime, land vehicles, and portable carrying cases.

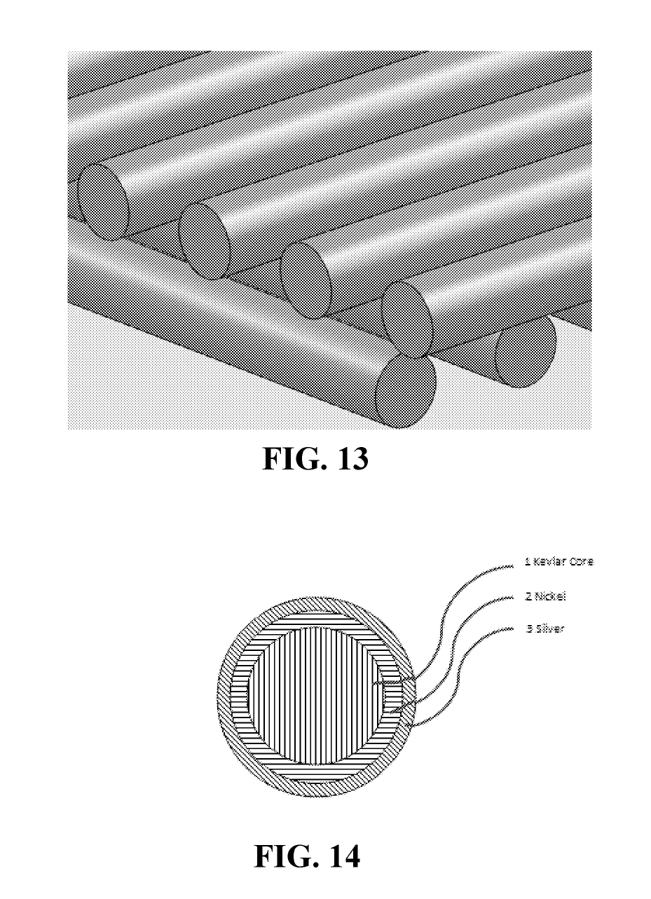

With reference to FIGS. 13-18, an exemplary embodiment of the present invention is illustrated and relates to a wire grid. The wire grid may be used for attenuation and polarization of electromagnetic fields from radio waves through infrared. The wire grid may also have a very broadband response and may be easily manufactured to create high-strength, lightweight structures.

With particular reference to FIG. 13, the wire grid includes arrays of cylinders that may or may not be in a periodic geometric arrangement. In the illustrated exemplary embodiment, the wire grid includes two arrays of wires arranged generally perpendicular to each other, with one wire array stacked on top of the other wire array. In other exemplary embodiments, the wires may be arranged in other geometric orientations and be within the intended spirit and scope of the present invention.

There are a number of ways to form a wire grid. The wire grid may be made out of strands or fibers or can be etched, deposited or otherwise placed onto a substrate. In some exemplary embodiments, the wire grid may be comprised of an array of long parallel cylinders. Several types of analysis may be performed on such an exemplary embodiment of the wire grid. First, a numerical scattering study may be performed that is based on analytical-closed form solutions for arrays of infinite cylinders. The scattering calculation may result in a scattering matrix tensor. From the scattering matrix tensor, the effective medium electric permittivity and magnetic permeability may be calculated as:

$$z = \sqrt{\frac{{( 1 + {S}_{11} )}^{2} - {S}_{21}^{2}}{{( 1 - {S}_{11} )}^{2} - {S}_{21}^{2}}}$$

$$n = \frac{1}{kd} {cos}^{- 1} [ \frac{1}{2 {S}_{21}} ( 1 - {S}_{11}^{2} + {S}_{21}^{2} ) ]$$

$$ɛ = n / z ( Electric Permittivity )$$

$$μ = nz ( Magnetic Permeability )$$

Where Sᵢⱼ are the Scattering Matrix parameters, k is the wave vector, z is the impedance and n is the refractive index.

A second type of analysis that may be is a band structure calculation. For such an analysis, the wire grid may be modeled as an array of harmonic oscillators. Other entities may have performed band structure calculation of meta-material structures before. However, in the present exemplary embodiment, three features are added to the model that other entities may not have added. Such features include: (1) coupling of harmonic oscillators to each other; (2) coupling of harmonic oscillators to a loss medium; and (3) the oscillators will have a geometrically-related distribution of fundamental frequencies. This methodology may be referred to as “Site-Specific, Coupled Harmonic Oscillator Model”.

Calculation of the dispersion relation and the hand structure of a meta-material may start with an assumption that a harmonic oscillator and thus the permeability, for example, may be modeled as a modified Lorentzian function:

$${μ}_{xx} = 1 - \frac{{A}_{m} {ω}^{2}}{{ω}^{2} - {ω}_{m 0}^{2} + i {ωγ}_{m}}$$

If the oscillators in the absence of coupling have individual and site-specific frequencies:

ωₘ₀

Where m is the site. Then the normal mode frequencies with inter-oscillator coupling will be:

$${ω}_{m 0}^{2} = {ω}_{i 0}^{2} - \frac{1}{{m}_{i}} {\sum }_{j}^{N} \frac{{x}_{i} {{ω}_{i} ( {a}_{i}^{v} {m}_{i} )}^{\frac{1}{2}} {C}_{ij} {{ω}_{j} ( {a}_{j}^{v} {m}_{j} )}^{\frac{1}{2}}}{1 - {\sum }_{j}^{N} {C}_{ij} {α}_{j}}$$

Where m and α are parameters of the individual oscillators and C is a parameter that represents the coupling between oscillators. If the oscillators are modeled as electric or magnetic dipoles then the individual parameters and coupling parameters are calculated for the forces between electric and magnetic dipoles respectively. The value of this analysis may lie in identifying a solution to providing broader bandwidth for meta-materials based on resonators. We found that coupling individual oscillators to external damping mechanisms significantly broadened the calculated and measured spectrum (of the electric dipole model for infrared spectrum of adsorbed molecules). The dispersion relation and thus the band structure may be calculated from the calculated normal modes.

A third type of analysis is a Finite Element Analysis (FEA) simulation. A commercial FEA program (e.g., COMSOL Multi-physics) may be used to perform this simulation. The FEA analysis may be less valuable at illuminating basic physics of the system, but the FEA analysis is better at estimating the real operation of a modeled system. The FEA analysis will use physical models created in a 3D mechanical modeling program (e.g., SolidWorks), assign electromagnetic properties to these physical structures, and then calculate.

We have identified several implementations of the grid metal material structure that are amenable to manufacture and may have existing applications in the market place. One possible way to form a product out of a grid meta-material is to create a fiber-resin composite. In some exemplary embodiments, carbon fiber may be used. Such carbon fiber may be Kevlar carbon fiber. Kevlar is lightweight and strong. However, it is not very good conductor. Thus, the Kevlar carbon fiber may be coated with a good conductor to make it a good conductor. Many example of polymers exist such as, for example, nylon rip-stop that has been coated with a variety of conducting materials giving single-sheet shielding effectiveness levels as high as 85 dB. The fibers may be coated with, for example, a combination of plasma etching, electro-less-plating, electro-plating and Chemical Vapor Deposition. Then, the grid of conducting fibers is molded into a composite panel. The panels must allow for interconnection to each-other and thus each panel will have a molded-in, thin conducting interface that will connect all the fibers together to provide a continuous conducting path throughout the panel. This type of construction allows for many possible shapes and may be easily accomplished with existing manufacturing methods. Products that might well be produced from this technology include protective cases, electronics enclosures, vehicle components, etc.

For injected molded plastics, several manners exist to implement a 3D grid pattern (e.g., laser activating and subsequent electro-less plating). Many examples of products exist that may be produced using this technology including, but not limited to, electronic enclosures for medical, consumer, and security markets.

High performance composites may be achieved by applying coating alloys. The effective electrical permittivity and magnetic permeability play an important role in effective shielding characteristics. The core material makeup and EM scattering and coupling geometries both play an import role in determining these effective medium parameters. The composition of the cylinders of the wire grid may be modeled using several different material compositions.

With reference to FIG. 14, an exemplary coated cylinder of the wire grid is illustrated. This exemplary cylinder includes Kevlar (Aramid) Fiber (e.g., 12 μm in diameter), Nickel (e.g., 1 to 2 μm thick), and Silver (1 to 2 μm thick). An exemplary manner of treating the cylinder to form this exemplary cylinder may be as follows: (A) Pretreatment—emulsified Turpentine, 175 F, 10 minutes; (B) etching—14 part Chromic Trioxide, 40 parts Sulfuric Acid, 46 parts water at 175 F; (C) sensitizing—0.6 part Stannous Chloride, 1.0 part Hydrochloric Acid, 98.4 parts water; (D) Activating—0.03 parts Palladium Chloride, 1 part Hydrochloric Acid, 98.97 parts water; (E) electro-less Nickel—29 parts Nickel Sulfate, 17 parts Sodium Hydrophosphite, 15 parts Sodium Succinate, 0.36 parts Succinic acid at 50 C for 20 minutes; and (F) electro-less Silver.

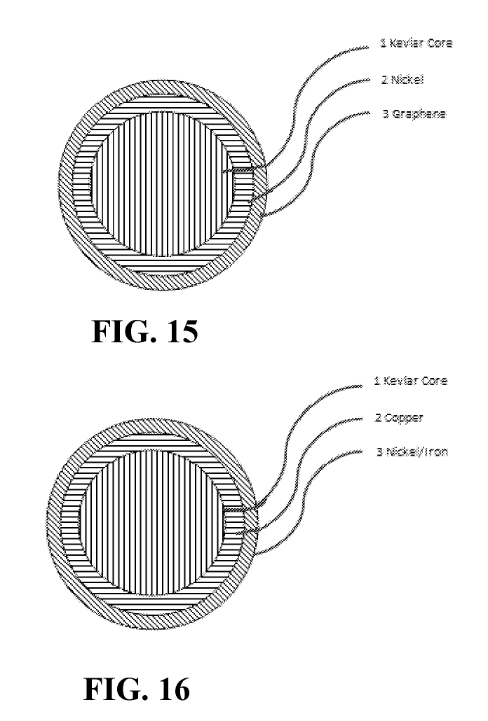

With reference to FIG. 15, a second exemplary coated cylinder of the wire grid is illustrated. This exemplary cylinder includes Kevlar (Aramid) Fiber (e.g., 12 μm in diameter), Nickel (e.g., 1 to 2 μm thick), and Graphene (e.g., 1 to 2 monolayer thick). High-quality sheets of a few layers of graphene exceeding 1 cm² (0.2 sq in) in area may be synthesized via chemical vapor deposition on thin nickel films. These sheets were successfully transferred to various substrates, demonstrating the viability of the technique for numerous electronic applications. This technique may be used on copper foils where the growth automatically stops after a single graphene layer, and arbitrarily large graphene films can be created.

Referring now to FIG. 16, another exemplary coated cylinder of the wire grid is illustrated. This exemplary cylinder includes Kevlar (Aramid) Fiber (e.g., 12 μm in diameter), Copper (e.g., 1 to 2 μm thick), and Nickel/Iron (e.g., 1 to 10 μm thick).

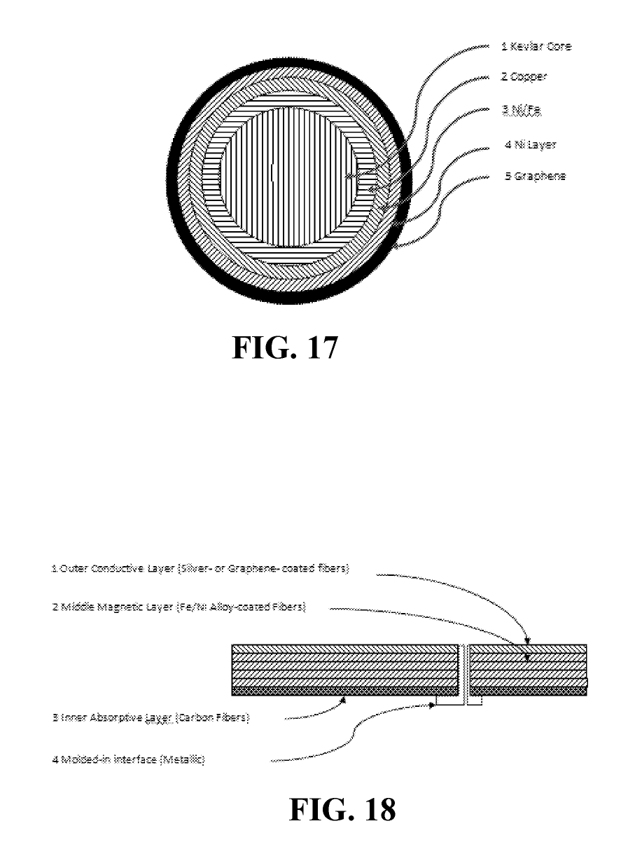

With reference to FIG. 17, a further exemplary embodiment of a coated cylinder is illustrated. This exemplary cylinder includes Kevlar (Aramid) Fiber (e.g., 12 μm in diameter), Copper (e.g., 1 to 2 μm thick), Ni/Fe (e.g., 1 to 2 μm thick), Nickel (e.g., 1 to 2 μm thick), and Graphene (e.g., 1 to 2 monolayer thick).

Upon creation of any of these exemplary embodiments of coated fibers or any other embodiments of coated fibers, the coated fibers may be combined to form a wire grid or cloth. The wire grid or cloth may be immersed in a resin to form a composite matrix. The wire grid or cloth may be combined in layers to provide an effective skin thickness with a performance to weight ratio that may be greater than that of solid metallic materials. With reference to FIG. 18, such composites may be used to form panels. In order to ensure continuous conductance of electric and magnetic flux through the composite and from panel-to-panel, the panels may be lined with a thin metallic strip that protrudes into the grid and connects the grid around the periphery. The panels may also include, among other things, an outer conductive layer (e.g., silver or grapheme coated fibers), a middle magnetic layer (e.g., Fe/Ni alloy coated fibers), an inner absorptive layer (e.g., carbon fibers), and a molded-in interface (e.g., metallic).

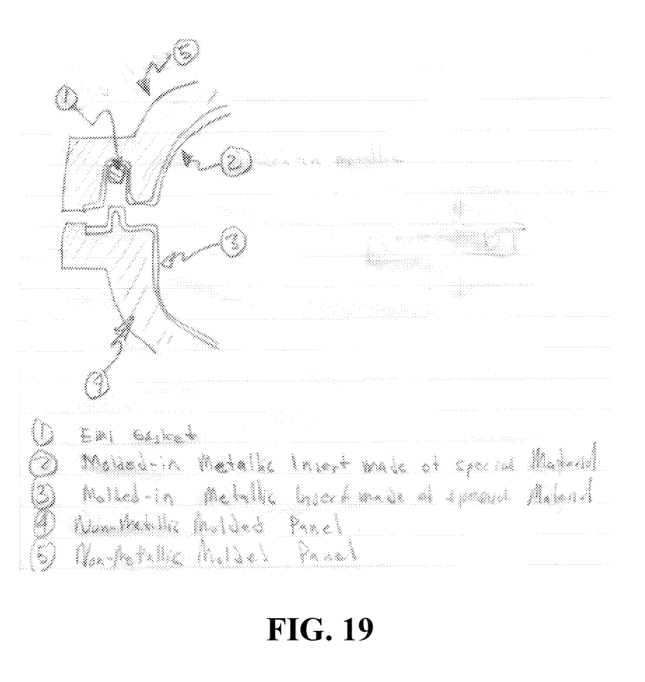

Referring now to FIG. 19, an exemplary embodiment of a personal carrying case is illustrated. Such a personal carrying case may be used for a variety of applications such as, for example, a case for an Attaché that may be carrying sensitive electronics and data. While EMP has been recognized as a threat since nuclear testing dating back to the fifties and while rugged Attaché cases have been made for decades, none of the cases appear to protect against EMP. In the illustrated exemplary embodiment, the carrying case may include a body having two mating components defining a cavity therebetween and a peripheral mating area around a portion of each of the two mating components for engagement with each other to adequately seal and close the carrying case. A liner may conform to an interior of the two mating components and fit in the cavity defined by the two components. IN some exemplary embodiments, the liner may be made of an electronically conductive and magnetically permeable material. A peripheral edge of the liner may be positioned near a peripheral area between the two mating components. The carrying case, when the mating components are closed, will maintain sufficiently high shielding effectiveness to protect electronic components stored therein.

With continued reference to FIG. 19, the liner may be comprised of a metal material welded to a peripheral mating flange of the two mating components with a gasket conformingly fit between the flanges of the two mating components. In some exemplary embodiments, the gasket may be a polymer EMI gasket and the polymer EMI gasket may conformingly fit into a durable polymer shell between the two flanges. The metal liner may be comprised of a steel alloy coated with multiple layers of alloys comprised of any or all of the following: Copper, Nickel, Cobalt, etc. In another exemplary embodiment of the carrying case, the liner may be comprised of a mu-metal plated, stamped steel shell and include a polymer EMI gasket conformingly fit into a durable polymer shell between the two mating components. In yet another exemplary embodiment of the carrying case, the liner may be comprised of a mu-metal plated, stamped steel shell and a durable polymer shell may not be incorporated. The construction allows the carrying case to provide EMP protection while being ergonomic, relatively low-cost, and aesthetic desirable.

With continued reference to FIG. 19, the carrying case includes two mating components connected by a hinge and closed with a latching mechanism. In some exemplary embodiments, the carrying case may be comprised of two thermoplastic mating components containing a molded-in metallic liner on interior surfaces of the components and a gasket that seals the two components. For example, the thermoplastic may be polypropylene or acrylonitrile butadiene styrene. Also, for example, the metallic liner may be steel, aluminum, or other formable metal. The liner may have coatings that increase the conductivity or permeability of the liner in order to achieve a high degree of shielding effectiveness. Instead of molded-in metallic insert, the liner may be comprised of coatings that increase the conductivity or permeability of the liner in order to achieve a high degree of shielding effectiveness.

In other exemplary embodiments, the carrying case may be comprised of two composite components or halves. The composite components may contain fibers in a resin matrix. The fibers may be comprised of high strength polymers such as, for example, Kevlar. The fibers may be coated with materials that have a high degree of conductivity and/or high degree of permeability and that may have a high magnetic saturation threshold. The fibers may be interconnected with metallic components that have high degree of conductivity and/or permeability and/or high magnetization saturation. The fibers may be interconnected with resins/polymer components that have high degree of conductivity and/or permeability and/or high magnetization saturation. It is desirable to provide continuity through the carrying case in order to maintain a high level of shielding effectiveness.

In further exemplary embodiments, the carrying case may be comprised of two advanced material components or halves. The advanced material may contain materials that have a negative refractive index. The negative refractive index materials provide a high degree of shielding effectiveness by diverting or otherwise excluding electric and magnetic fields from the interior of the carrying case.

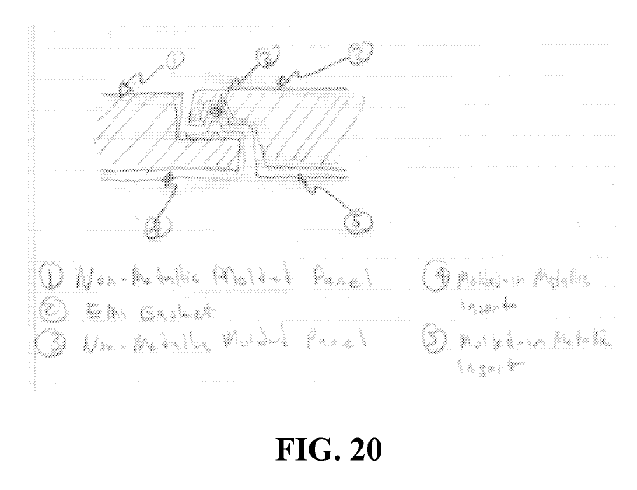

With reference to FIG. 20, another exemplary embodiment of a carrying case is illustrated. In this illustrated exemplary embodiment, the carrying case may include a rugged shielded composite panel system that utilizes interconnecting panels to achieve a conformal external skin. This embodiment may be used in a variety of applications such as, for example, aircraft, maritime vehicle, land vehicle, etc. This carrying case includes a pair of non-metallic molded panels, a pair of molded-in metallic inserts or liners, and an EMI/EMP gasket.

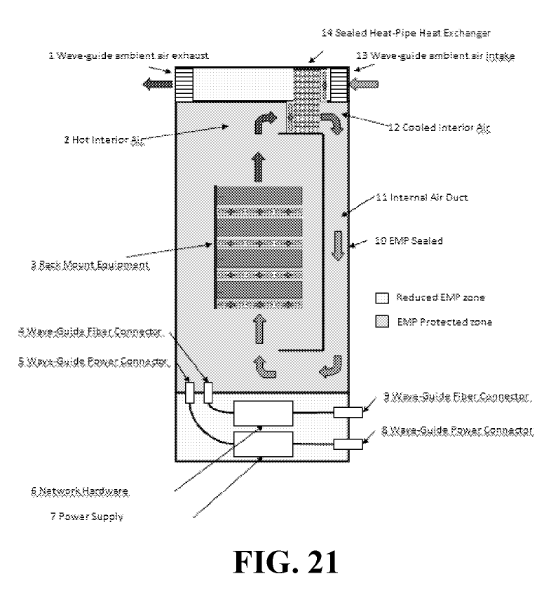

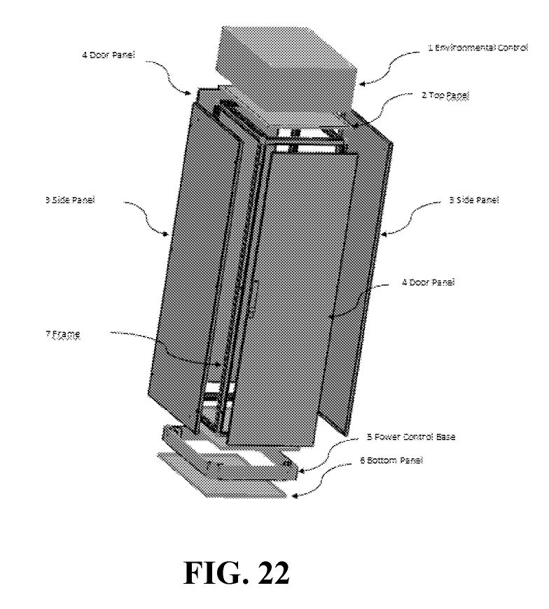

Conventional data center cabinets, enclosures, and racks do not possess provisions for protecting the electrical contents from either low power or high power EMI. With reference to FIG. 21, an exemplary embodiment of an enclosure is illustrated and provides protection against EMI. The enclosure includes a housing or panels that limit EMI inside the enclosure, a power source that penetrates the enclosure and is designed to limit EMI inside the enclosure, a thermal management system that cools electrical contents of the enclosure and limits EMI inside the enclosure, and a communication interface that allows communication with equipment inside the enclosure and is designed to limit the EMI inside the enclosure. In some exemplary embodiments, the enclosure may be constructed out of a variety of metals and metal alloys. In other exemplary embodiments, the enclosure may be constructed out of a variety of functionalized composite materials. Such composite materials may include various structures including carbon fiber, grapheme, metallic nano-particles, among others. In further exemplary embodiments, the enclosure may be constructed out of a variety of advanced materials that are composite, alloys and structure-based (e.g., meta-material) materials. The enclosure includes all items necessary to protect contents against radiated and conducted EMP. Referring to FIG. 22, the enclosure may be modular in design and include a frame and sealed, shielded panels.

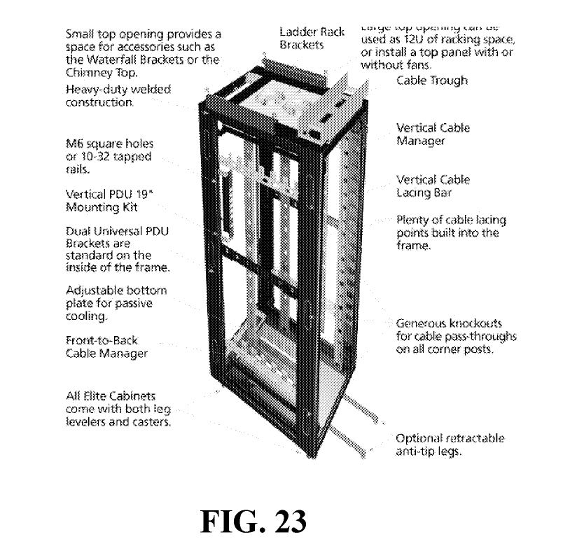

Referring to FIG. 23, a conventional enclosure is illustrated for supporting electrical devices. This conventional enclosure does not have physical protection characteristics for protecting against EMP/EMI.

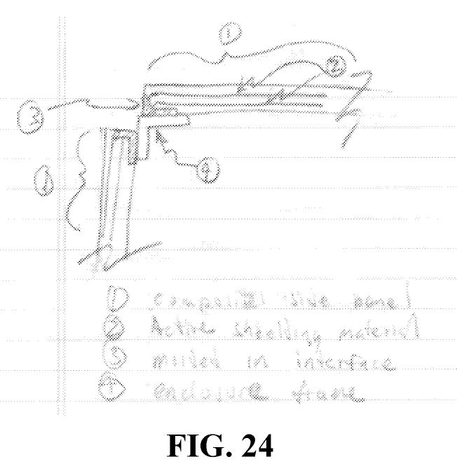

Referring now to FIG. 24, an exemplary embodiment of a connection between a composite shielding panel and an enclosure frame is illustrated. FIG. 24 illustrates a pair of composite side panels, active shielding material, molded in interfaces, and an enclosure frame.

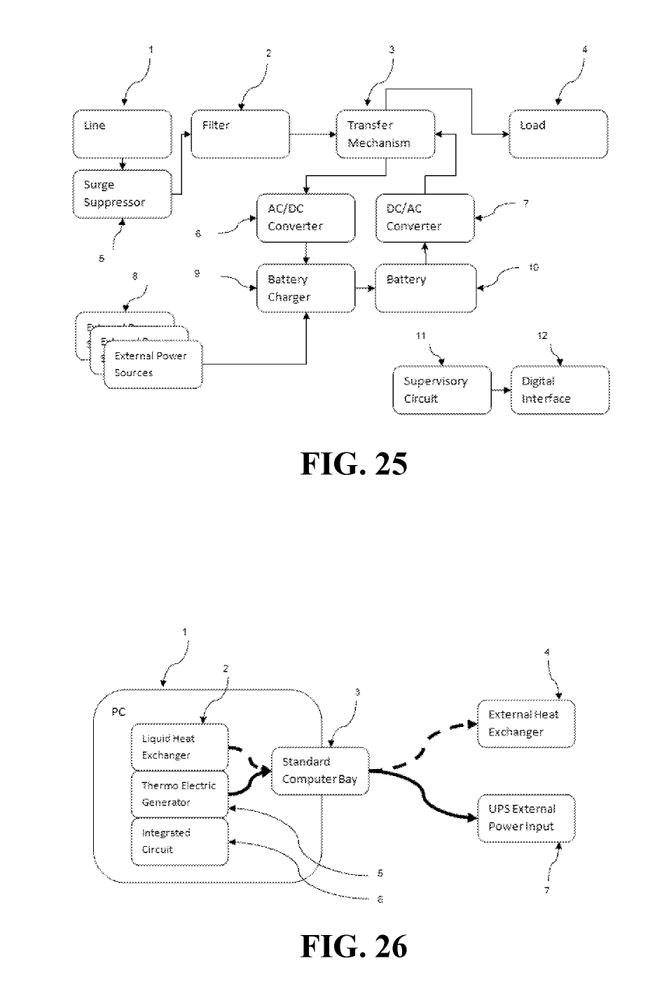

With reference to FIG. 25, an exemplary embodiment of an integrated battery backup system and thermal control system with the integrated battery backup system including a component that converts waste heat from the thermal control system into electricity that is stored in the battery backup system. FIG. 25 is an exemplary block diagram that illustrates integrated protection, power harvesting, uninterrupted power supply, and battery backup. The system includes a power source 1 that may be a wide variety of power sources such as, for example, an AC power source that includes, but is not limited to, 120 VAC 60 Hz, 240 VAC 60 Hz, 240 VAC 50 Hz, 230 VAC 3 Phase 60 Hz, 480 VAC 60 Hz, or other common or uncommon AC power sources. The system also includes a filter 2 comprised of frequency-dependent components capable of passing desirable frequencies of electromagnetic signals and attenuating undesirable frequencies of electromagnetic signals. The filter many include, but is not limited to, any of the following: capacitor, capacitor-inductor, inductor-capacitor, PI or other passive filtering design. The integrated design for the filtering may contain integrated magnetic and dielectrics for optimal performance and reduced size.

With continued reference to FIG. 25, the system additionally includes a transfer mechanism 3 that may include, but is not limited to stand-by USP design, Line-interactive USP design, Ferro-resonant USP design, Double-Conversion USP design, Delta conversion USP design, etc. In some exemplary embodiments, double conversion USP may provide high efficiency and excellent protection. Further, the system includes a load that may be a wide variety of electronic devices such as, for example, a server or other electronic devices. The output may be power factor corrected for optimal efficiency. Additionally, the system may include a surge protector. The surge protector may be comprised of a Metal Oxide Varistor (MOV), Vanadium Oxide Suppressor, Spark Gap, Silicon Avalanche Diode, or other voltage-dependent protection devices. The system also includes a AC/DC converter capable of converting line-level AC current to bus-level DC current using transformers, inductors, dielectrics and rectifiers. The AC/DC converter may include integrated inductor, capacitor and transformer for superior performance and small footprint. The system further includes a DC/AC converter capable of converting DC bus current to the load current. Techniques to perform this conversion include multiphase buck, multiphase buck with integrated controller, integrated power electronic modules, coupled inductor converters, DCX, multi-stage VR, multi-frequency buck, or current mode digital converter. The package may include 3D integration of transformers, inductors, dielectrics and digital components. Further yet, the system includes an external power source that may be from a single or multiple energy harvesting inputs. These inputs may include a thermo-electric device that converts a temperature differential into electrical current. The input may be a solar panel that turns light into electrical current. The input device may be a broadband RF receiver that turns radio frequency radiation into electrical current. The input may be an advanced meta-material that converts thermal radiation into electrical current. The input may be an optical antenna that turns thermal and infrared radiation into electrical current.

With further reference to FIG. 25, the system further includes a battery charger that converts electrical current into stored charge that is optimized for the chemistry of the electrical storage device. The electrical storage device may be a number of different battery technologies that convert electrical energy into chemical energy for the purposes of energy storage. Additionally, the system includes a battery comprised of a device that takes electrical energy, converts it to chemical energy for storage purposes and then allows the chemical energy to be converted back into electrical energy to power devices. Further yet, the system includes a supervisory circuit that may contain digital processing logic that optimizes the operation of the energy harvesting battery backup system. The system also includes a digital interface capable of providing a means to communicate with other machines via a Machine-Machine-Interface (MMI) or to humans via a Human-Machine-Interface (HMI) or user interface.

Referring now to FIG. 26, an exemplary system for harvesting electrical energy from a PC Microprocessor with an external Liquid-based heat exchanger is illustrated. The exemplary system includes an electronic device such as a personal computer (PC) 1, a server, a desktop PC, or other electronic devices that may normally use heat-sink technology for cooling of electrical components. The system also includes a liquid heat exchanger 2 that provides a cool-side thermal sink for the thermoelectric converter. Additionally, the system includes a thermoelectric generator 3 adapted to convert thermal energy from the integrated circuit into electrical current. Such a conversion may be performed in a variety of manners and one such exemplary manner includes the Seebeck effect. Further yet, the system includes a standard computer bay bulkhead 4, or other electronic bulkhead may be used as an interface to transfer fluid or electronic current from within the PC enclosure to external components.

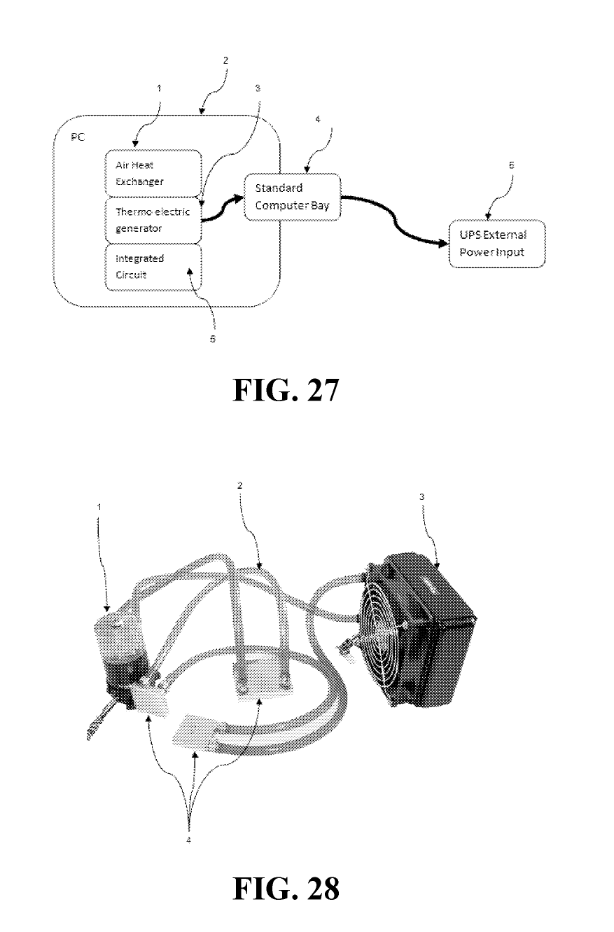

With reference to FIG. 27, an exemplary system for harvesting electrical energy from a PC microprocessor with external air-based heat exchanger is illustrated. A CPU energy harvesting member is attached to the microprocessor and the harvesting member includes thermoelectric generator, air heat exchanger and a fan.

Referring now to FIG. 28, an exemplary system for liquid-based thermal management and energy harvesting system for direct cooling of electronic components is illustrated. The system includes a pump 1 that circulates liquid through the system, tubing 2 that caries fluids to various parts of the system, a liquid-air heat exchanger 3 for transferring thermal energy between the liquids and ambient air environment, and harvesting elements 4 that draw heat from the electrical components and utilize the cooled liquid to power the thermo-electronic generation element based on, for example, the Seebeck effect.

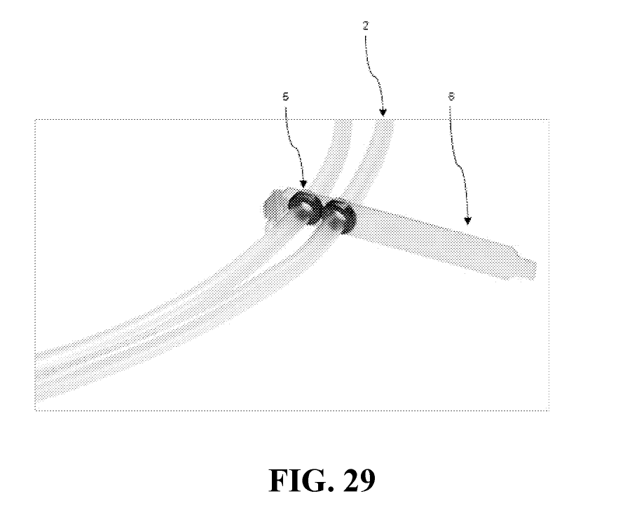

With reference to FIG. 29, tubing 2, grommets 5, and a standard PCI bulkhead 6 are illustrated. The tubing 2 may be used to transfer fluid between PC and cooling system. The coolant may include non-conductive fluids that are safe for operation in an electronic environment. Example coolants include, but are not limited to, Fluorinert. The bulkhead 6 assists with retrofitting the system within a desired environment.

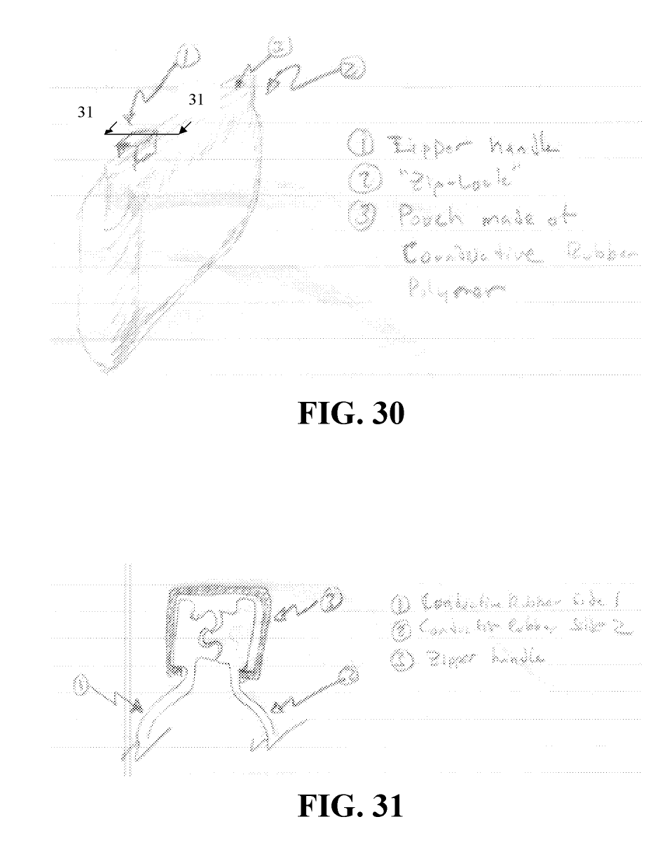

Referring now to FIG. 30, an exemplary soft sided protective carrying case or enclosure is illustrated. The enclosure includes a body having two mating components with each mating component including a peripheral area for mating engagement between the two components. When the components are closed, the peripheral areas engage in a sealed relationship. A liner may be conformingly fitted in a cavity defined by the two mating components. In some exemplary embodiments, the liner may be made of an electronically conductive and magnetically permeable material. Peripheral edges of the liner are arranged for location in the peripheral areas of and between the two mating components. The enclosure, when the mating components are closed, will maintain sufficiently high shielding effectiveness to protect electronic components stored therein. With continued reference to FIG. 30, the illustrated exemplary embodiment is a soft sided case including an exterior thereof made of a soft conductive rubber polymer, a closure mechanism such as, for example, a zipper-like mechanism, and a closure actuator such as, for example, a zipper-like actuator for closing and opening the zipper-like mechanism.

With reference to FIG. 31, a cross-sectional view of a portion of the soft sided enclosure is illustrated. The enclosure includes the two conductive rubber polymer components, the interlacing closure mechanism, and the closure actuator engageable by a user to open and close the closure mechanism.

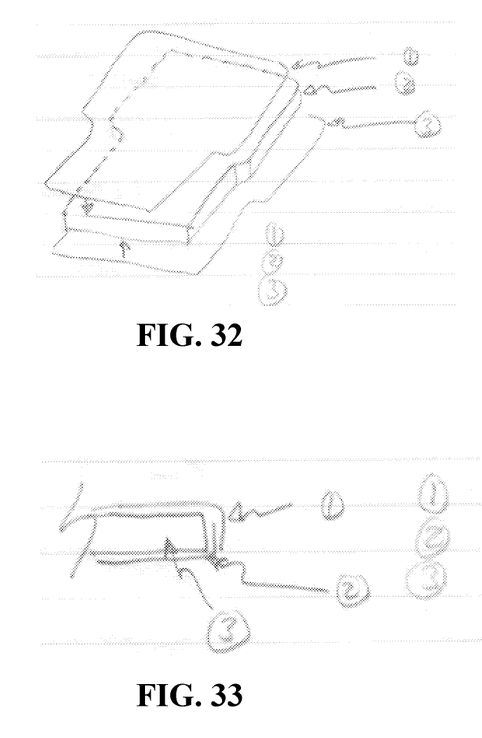

Referring now to FIG. 32, an exemplary embodiment of a multi-layered soft sided enclosure is illustrated. The multilayered enclosure includes an interior layer 1 of conductive and/or magnetically permeable material, an intermediate layer 2 of protective material that could be, for example, neoprene, and an outer layer 3 of conductive and/or magnetically permeable material.

With reference to FIG. 33, another exemplary embodiment of a multi-layered soft sided enclosure is illustrated. In this exemplary embodiment, the enclosure covers an intermediate layer of material with electromagnetic protective layers to maintain electrical and magnetic continuity. The enclosure includes an interior layer 1 of conductive and/or magnetically permeable material, an intermediate layer of protective material that could be, for example, neoprene, and an outer layer 3 of conductive and/or magnetically permeable material. The interior and outer layers of material are overlapped and bonded together to retain electronic and magnetic continuity.

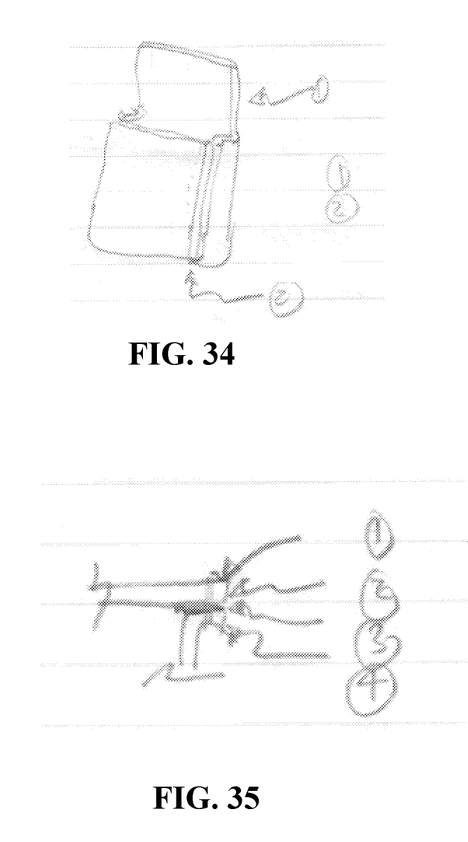

Referring to FIG. 34, a further exemplary embodiment of a soft sided enclosure is illustrated. The enclosure includes a body 2 and a cover 1. The body defines a cavity and is sealed around its periphery. The cover seals the enclosure and cavity in order to maintain electrical and magnetic continuity.

Referring now to FIG. 35, a manner of physically bonding a joint of a soft sided enclosure is illustrated. Any of the exemplary embodiments of soft sided enclosures disclosed herein may incorporate the illustrated manner of physically bonding a joint. A first piece 1 of material and a second piece of material 3 are desired to be joined. A material 2 is used to bond the first and second pieces 1, 3 of material that make up the enclosure. The bonding material 2 properties maintain the electrical and magnetic continuity of the enclosure. A thread 4 of other physical bonding mechanism assists in maintaining the mechanical integrity of the bond. The thread 4 may also have properties that are used to maintain the electronic and magnetic continuity of the bond.

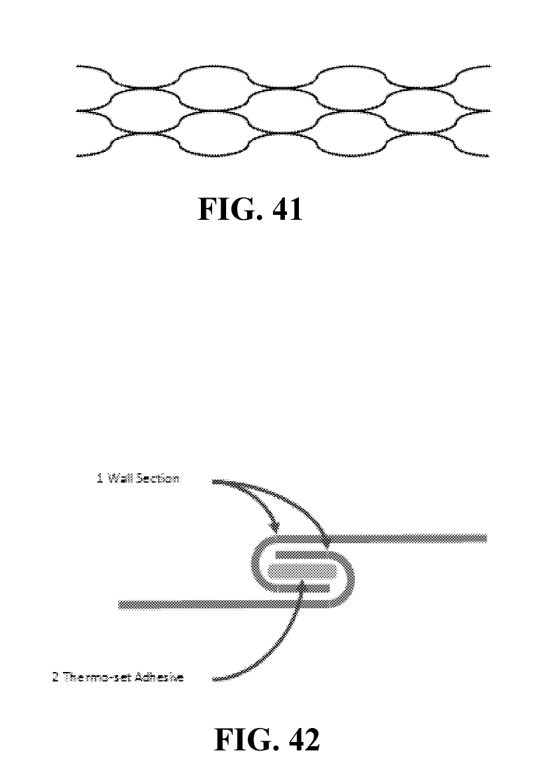

In some exemplary embodiments, a protected and energy efficient tent insert is provided that may be used with an existing tent (see FIG. 41) to maintain thermal, electrical and magnetic environments within the tent. The exemplary embodiment includes bonding wall-to-wall, bonding floor-to-wall, bonding wall-to-door, environmental control, power, and communication that allow manufactured structures to also meet proposed requirements.

Magnetic-field attenuation may be achieved by means of a screen made of a magnetic material combining high permeability (μ>>1) with sufficient thickness to attract the material's magnetic field by providing a low-reluctance path. Alternatively, a thin shield made of a conductive material with low permeability can also provide effective shielding for magnetic fields, because an alternating magnetic field will induce so-called eddy currents in the screen (assuming, that is, that the shield has adequate conductivity). These eddy currents will themselves create an alternating magnetic field of the opposite orientation inside the shell. The effect will increase as frequency increases, resulting in high shielding effectiveness at high frequencies.

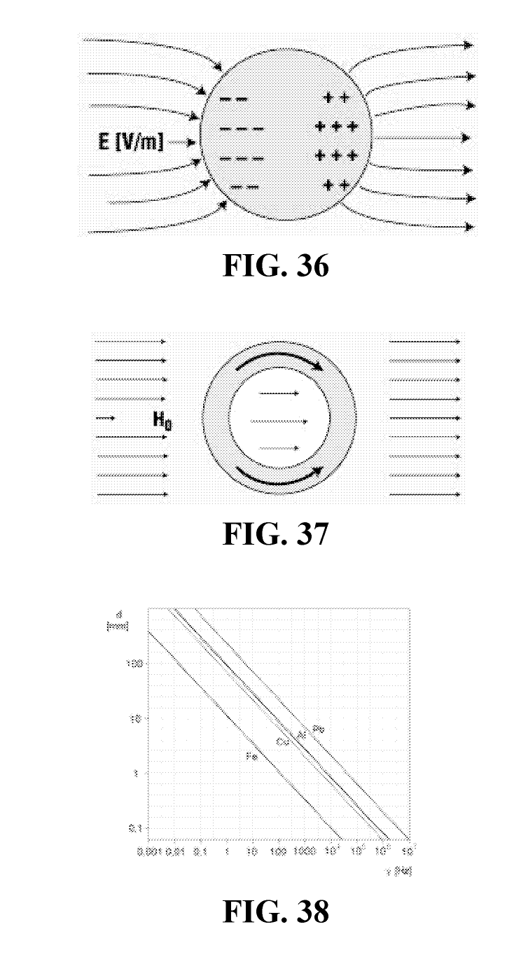

Referring to FIG. 36, a good conductor is illustrated and the charge of the conductor is free to redistribute in order to provide a zero electric field inside a conductor. This property is used to shield contents from affects of external electric fields. Plane magnetic waves induce current on good conductors that rearrange currents and allow good conductors to shield against magnetic plane waves. FIG. 37 illustrates non-plane waves that are not effectively shielded by conductors and must be shielded with a magnetic material. With reference to FIG. 38, effectiveness with which a material will shield an electric field depends on both the conductivity and frequency

Therefore, a good solution for EM attenuation, based on the discussion above, would be to construct a thick enclosure of a very good conductor (e.g., gold or silver) and line it with a thick layer of magnetic material (e.g. “mu-metal”). This type of construction may not be practical for military purposes from the standpoint of cost, weight, expense, and/or manufacturability.

An exemplary solution to the shielding problem identified in the previous paragraph is to create an advanced material composite that incorporates both material properties and material geometry to create a shielding solution that is strong, lightweight, producible at a reasonably low cost, and easy to manufacture. Thus, a variety of single and multi-layered fabrics that provide shielding characteristics at both low frequencies and high frequencies using a variety of metallic coating blends may be provided to resolve the above-identified problem.

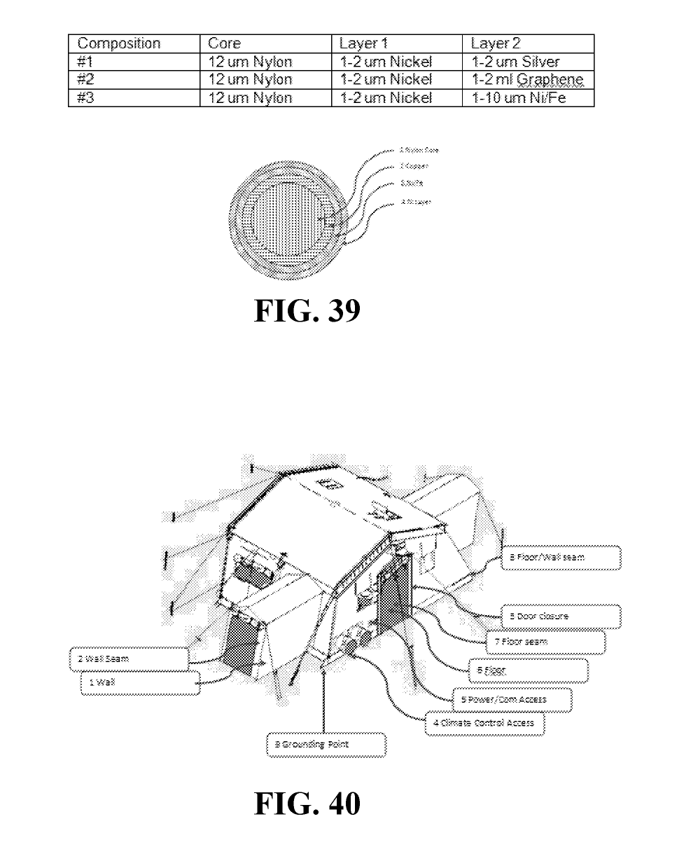

With reference to FIG. 39, an exemplary embodiment of a fiber of a high performance material is illustrated. Effective electrical permittivity and magnetic permeability may play an important role in effective shielding characteristics. The core material makeup of the fiber and EM scattering and coupling geometries of the fiber both play an import role in determining these effective medium parameters. The fiber of the high performance material may have a variety of different compositions and be within the intended spirit and scope of the present invention. FIG. 39 illustrates three such exemplary compositions. These exemplary compositions are not intended to be limiting upon the present invention.

The exemplary fiber of the high performance material may be formed in a variety of manners. One exemplary manner of forming the fiber includes: Pretreatment—emulsified turpentine, 175 F, 10 minutes; etching—14 part Chromic Trioxide, 40 parts Sulfuric Acid, 46 parts water at 175 F; sensitizing—0.6 part Stannous Chloride, 1.0 part Hydrochloric Acid, 98.4 parts water; activating—0.03 parts Palladium Chloride, 1 part Hydrochloric Acid, 98.97 parts water; electro-less Nickel—29 parts Nickel Sulfate, 17 parts Sodium Hydrophosphite, 15 parts Sodium Succinate, 0.36 parts Succinic acid at 50 C for 20 minutes; and Electro-less Silver.

With particular reference to FIG. 40, an exemplary soft sided structure is illustrated and such soft sided application requires electromagnetic protection. In the illustrated exemplary embodiment, the soft sided structure is a tent. FIG. 40 identifies some of the locations of the structure having weak electromagnetic shielding. The tent, tent insert, and material or fabric of the present invention is adapted to improve the electromagnetic shielding at these weak locations.

In some exemplary embodiments, a target fabric weight is about 10 to about 15 oz/yd or 300 to 1050 Denier. Many of the considered materials are about 70 Denier. Thus, up to about 15 layers of 70 Denier fabric could be combined and still meet the weight requirement.

With reference to FIG. 41, an exemplary embodiment of a multi-wall fabric is illustrated and may include multiple layers of 70 Denier fabrics bonded in a cellular pattern. In this illustrated exemplary embodiment, the fabric includes an outer layer that may be comprised of a superior conducting fabric (e.g., coating schemes associated with FIGS. 14 and 15), which may have the best high-frequency response. The fabric may also include inner layers that may comprise high permeability fabric (e.g., coating scheme associated with FIG. 16), which may have the best low frequency response. The multiple layers may be connected by adhesive bonding. The layers may be filled with air to provide thermal insulation. The inner layer could be coated with aluminum film for superior reflectance in the infrared that will result in improved thermal performance as an insulating insert.

As indicated above, the system accounts for bonding wall-to-wall, bonding wall-to-floor, and securing a door in structures desired to provide electromagnetic protection. The system is adapted to achieve these features and be reliably manufactured and used. One aspect of the structures of particular concern is the seams. The system includes a seam mechanism that is both easy to manufacture and will be durable to the operational environment. The seam consists of a interlocking fold that maintains continuity with both of the fabric surfaces. A special conductive thermo-set adhesive is used for the seam. Additional strength may be added with metalized thread.

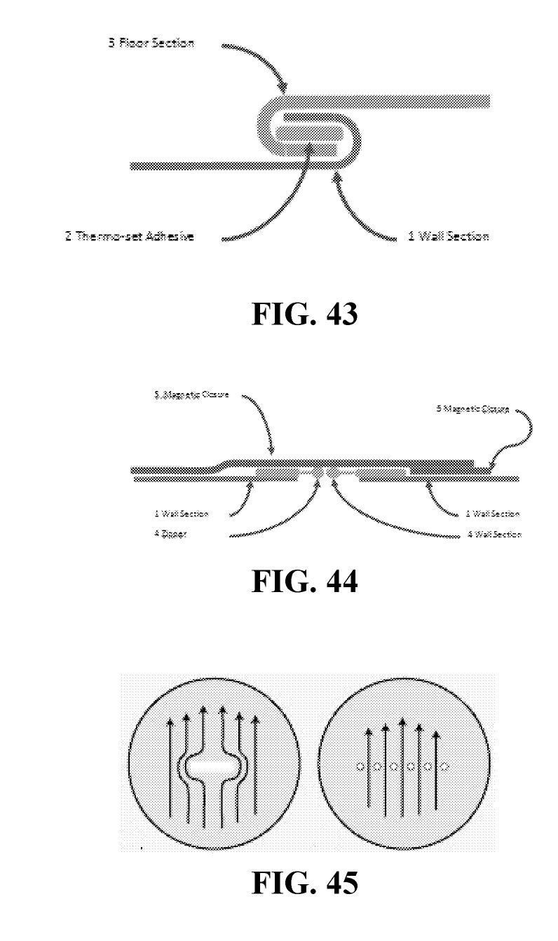

One particularly important challenge is making sure the structure can be reliably manufactured and used. One potential problem area is the seams. With reference to FIGS. 42 and 43, the seam of the system is both relatively easy to manufacture and will be durable to the operational environment. FIG. 42 illustrates a wall-to-wall seam and FIG. 43 illustrates a wall-to-floor seam. The seam comprises of an interlocking fold that maintains continuity with both of the fabric surfaces. A conductive thermo-set adhesive may be used for the seam. Additional strength may be added with metalized thread. Connections between fixed seams may be bonded with a highly conductive and permeable thermo-set adhesive that is active by heating (e.g., from RF source).

Another potentially problematic area is the door of the structure. Users flex this portion of the enclosure more than any other part of the tent/liner. The door has to be durable to multiple entries and not be difficult to use or inhibit the user's mission workflow. The door may comprise a zipper capable of being made out of wide variety of materials such as, for example, copper and nickel plated, to maintain continuity. A special magnetic closing strip may be added to the structure or tent opening in order to maintain a sealed closure. The idea is that as long as the zipper is closed, the magnetic strip will seal the opening automatically. This relieves the user from having to pay close attention to the seal on the door. Additionally, the system may include a resonant liner for the door that will use meta-materials to minimize ingress of electromagnetic radiation at the seams. Further, the system may include a spring steel form to the seam surrounding the doorway. This may create a passive “automatic door”. The combination of spring steel form and magnetic latch will reduce concern about closing the door and could maximize both workflow and effectiveness of the tent insert.

Referring to FIG. 44, the door may have a magnetic closure that will assist in making sure the door is closed and sealed. In addition, meta-material may be provided around the door to minimize leakage around door. Further, the door may be zipper-less and instead may use a spring steel insert in concert with a magnetic closure to automatically latch the door.

The system also includes exemplary embodiments of protecting low-profile penetrations or apertures in a structure. Any apertures or breaks in a shield will limit its effectiveness. Since the theory behind magnetic-field shielding via induced currents presumes that such currents will flow as long as there are no obstacles in their path, it is essential that any and all apertures be arranged in such a way as to minimize their effect on the currents. Note, too, that apertures have HF resonances, so an (induced) HF current flowing on the structure may cause the aperture to act as a transmitting antenna. In order to be effective, a shield must be as tight as possible. The presence of intentional and, inevitably, unintentional-apertures (e.g., everything from doors, windows, ventilation holes, and inlets for panel instrumentation to seam gaps, cable throughputs, among other things) will lower the shielding effectiveness of a structure. A magnetic and an electric field, respectively, will pass through a hole and induce interfering currents or voltages on an underlying components and disturbances will be induced on internal components whenever an H-field surrounds it or an E-field falls along it.

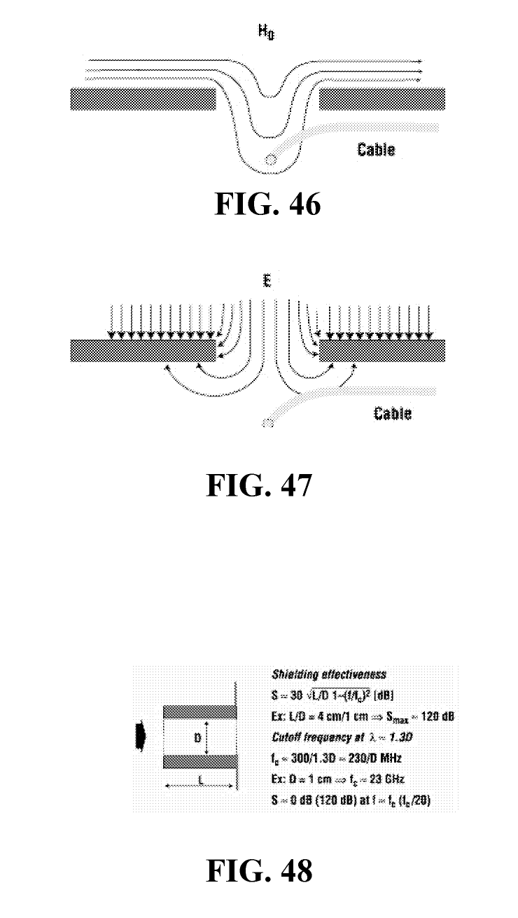

With reference to FIGS. 45-47, openings and apertures act as resonators and allow EM waves to penetrate the shielded enclosure.

If an aperture in a shielded structure or enclosure is to be used to allow a length of plastic tubing to pass through (e.g., as for a water or an air inlet), a mechanical waveguide may be used as a filter for electromagnetic waves with frequencies well below its cutoff. Such a cutoff filter may take the form of a circular or rectangular tube. Note, however, that the attenuation may decrease with frequency and become zero at the cutoff. This cut-off frequency is a function of the geometry of the waveguide. Referring to FIG. 48, a waveguide feed-through is a solution for small apertures, but has a large physical standoff profile.

The waveguide feed through is fine for EMI test rooms where space is not an issue. However, in general having a long tube protrude in and out of enclosures may not be ideal. Furthermore, many times there is an un-intentional opening in an enclosure. For example, a gasket lined cover is left slightly ajar or the gasket is not in good repair. The system of the present invention addresses these types of aperture penetrations with resonant meta-material solutions.

Meta-materials may include, for example, Slit Ring Resonator (SRR) and such meta-materials may have negative refractive index near the resonant frequency of the SRR. Resonant structures have apparent, narrow band, ability to exhibit super-diamagnetic, diamagnetic, paramagnetic and super-paramagnetic behavior.

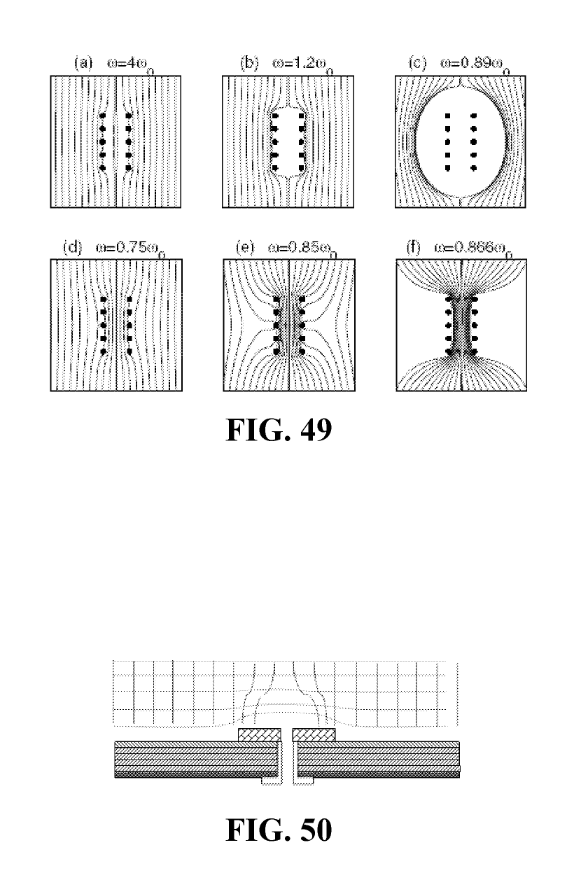

With reference to FIG. 49, an array of capacitive coupled split ring resonators may achieve paramagnetic or diamagnetic behavior depending on the relationship to the resonant frequency.

These types of resonance and other radio-frequency design techniques are used to address apertures in the enclosures. The orientation of the E and M fields are constrained in the vicinity of the aperture due to the conductors. Thus, a solution for a wide angle of incidence is solved by resonant structures disclosed herein, and focus efforts on what comes down to an Antenna matching problem. That is, the aperture will be detuned by application of planar-3D resonant structure around the aperture.

Referring to FIG. 50, an appropriate arrangement of resonant low-profile resonant structures surrounding an opening allows for improved performance without adding significant thickness to the enclosure wall.

Planar resonant structures are arranged around an opening and achieve at least 40 dB improvements over the opening without the structures in place. Two exemplary scenarios where openings are present in a structure and electromagnetic protection of the openings are desired include, but are not limited to: (1) a small circular opening used to vent an enclosure; and (2) an opening at a door closure.

Shielding effectiveness of a variety of fabric samples may be measured. For example, the shielding effectiveness of fixed (e.g., wall-to-wall and floor-to-floor) and moveable (e.g., door) closures may be measured. Shielding effectiveness (SE) refers to the ratio of electromagnetic field intensity of no shielding to after shielding with the unit of measure in decibel (dB). The expression is shown in as follows.

$$SE = 20 lg \frac{\vert {E}_{1} \vert}{\vert {E}_{2} \vert}$$

Where E₁ is electric field intensity without shielding, while E₂ is electric field intensity with shielding. Shielding Effectiveness may be measured following the guidelines of ASTM E 1851-04.

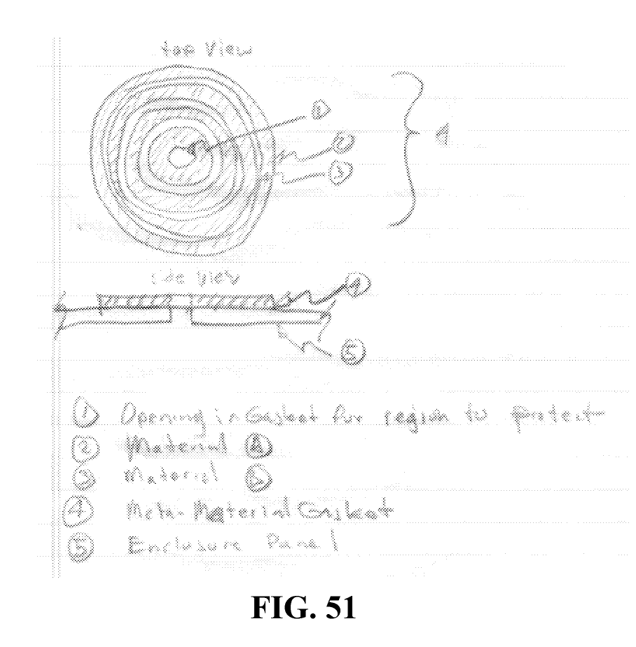

With reference to FIG. 51, an exemplary embodiment of a low-profile EMI material gasket or member 4 is provided for protecting an aperture in a fixed portion of the enclosure such as, for example, a wall panel. The low-profile EMI member 4 is used to provide EMI protection to the opening 1 in a panel 5 of the enclosure or structure. The member 4 includes a plurality of spaced-apart concentric ring members. The ring members may be made of the same material or may be made of different materials. The thickness or height of the ring members is relatively small, thus providing a relatively low profile.

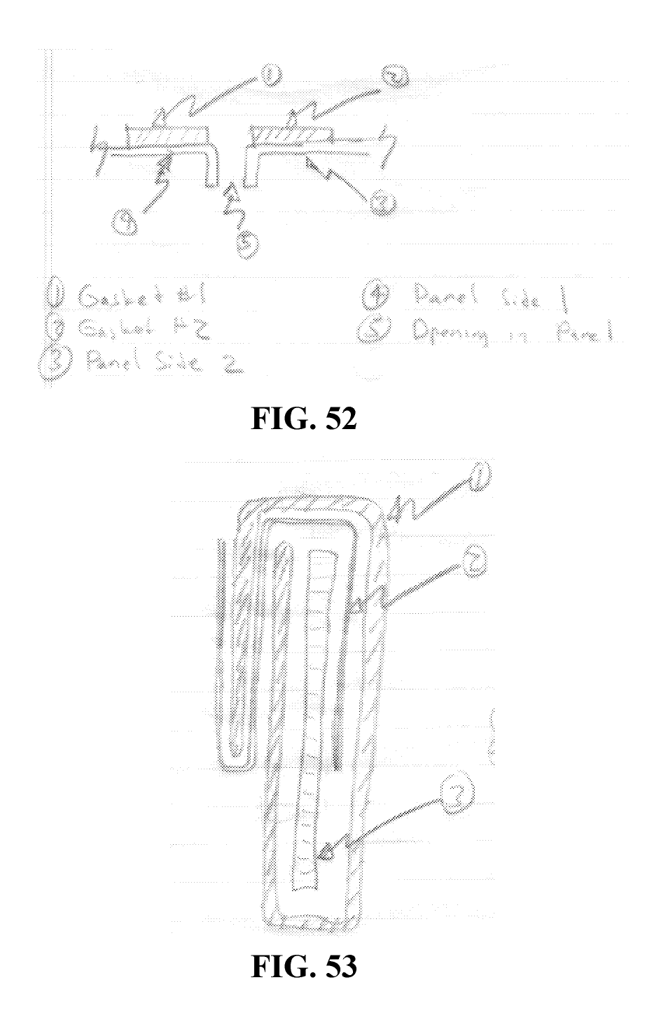

Referring now to FIG. 52, an exemplary embodiment of a low-profile EMI material gasket or member is provided for protecting an aperture associated with a moveable portion of the enclosure such as, for example, a door or window of the enclosure. An opening 5 associated with a door will be defined between a pair of spaced apart enclosure panels 3, 4. The low-profile EMI member includes a first gasket or member coupled to the first enclosure panel 3 and a second gasket or member coupled to the second panel 4.

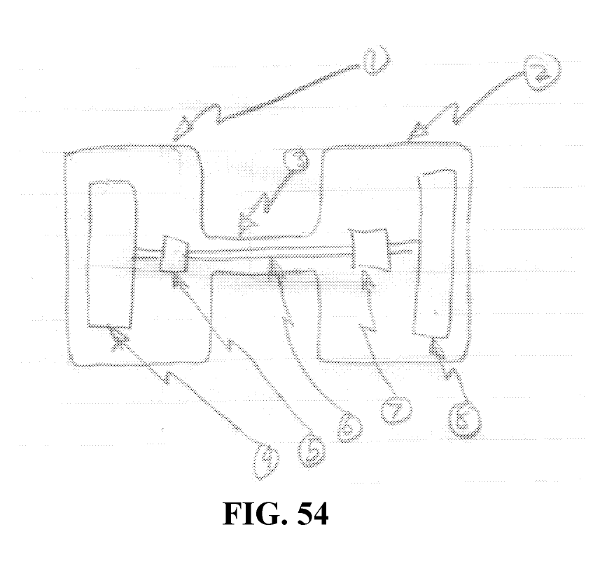

With reference to FIG. 53, an exemplary embodiment of a device for protecting a wireless device from EMP while still allowing use of the device is illustrated. In some exemplary embodiments, the device may be a soft-sided device. In such an exemplary embodiment, the device defines a cavity for supporting a wireless device 3 and includes an antenna subsystem module 2. In some exemplary embodiments, the antenna subsystem module may be a passive antenna. Referring now to FIG. 54, the antenna subsystem module includes an outer antenna substrate, an inner antenna substrate, a flexible electronic substrate, an outer antenna, outer protective filter electronics, a feed through wave-guide, inner protective filter electronics, and an inner antenna.

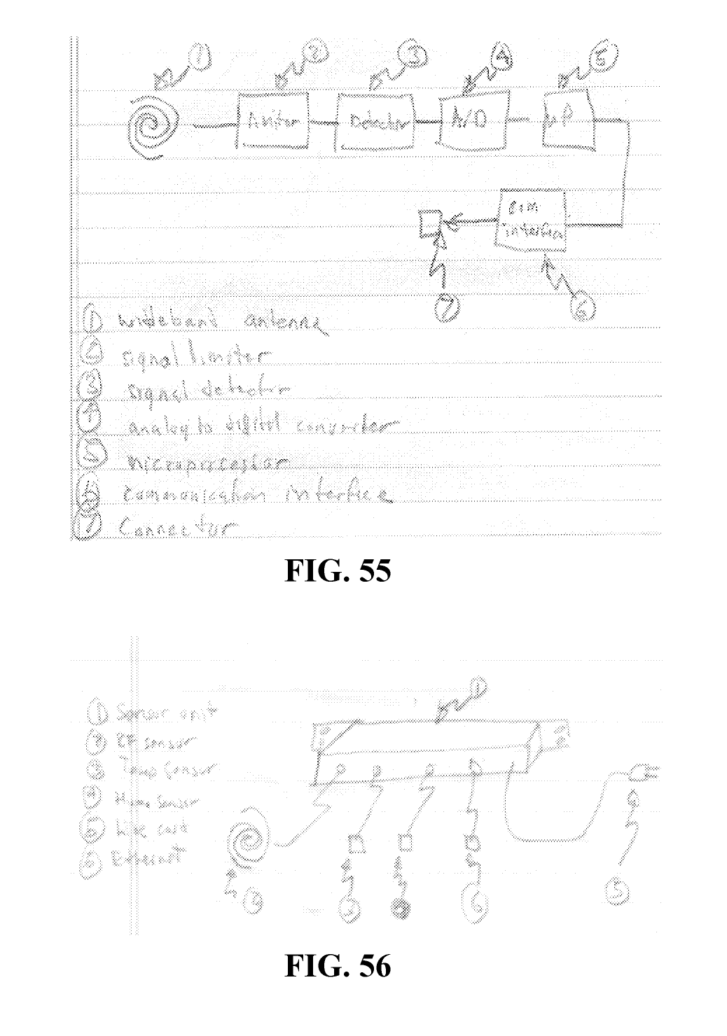

Referring to FIG. 55, a block diagram of an exemplary embodiment of an integrated EMP sensor of an integrated system monitor is illustrated. In some exemplary embodiments, the integrated system monitor allows monitoring of server cabinets parameters such as, for example, temperature, humidity, presence of water, breach of enclosure and also may allow the measurement of power quality and the presence of EMP or EMI signals. In the illustrated exemplary embodiment, the integrated EMP sensor may include a wideband antenna, a signal limiter, a signal detector, an analog to digital converter, a microprocessor, a user interface, and a connector. Conventional systems may exist that measure temperature, humidity, presence of water, and other common parameters. The exemplary embodiment of the present invention measures radiated EMI/EMP. The sensor may integrate into existing monitoring systems or provide its own standalone interface. The interface will facilitate communication through an Ethernet, USB, Serial or other common communication connection. The system may also include software that runs on the microprocessor that is included in the sensor and enterprise software that is implemented on a server or through cloud computing services. This software will provide business intelligence as to the existence of EMI/EMP within the enclosure and will report description of the type of EMI/EMP along with time and date stamps.

Referring now to FIG. 56, a module layout of another exemplary embodiment of an integrated EMP sensor of an integrated system monitor is illustrated. In the illustrated exemplary embodiment, the integrated EMP sensor includes a sensor unit, an RF sensor, a temperature sensor, a humidity sensor, a line cord, and an Ethernet connection.

In some exemplary embodiments of the present invention, a fast pulse detector is provided. The fast pulse detector is a sensor device or system capable of detecting electromagnetic pulses with pulse widths as short as 100 picoseconds through a combination of a custom-designed Ultra Wide Band (UWB) fractal antenna integrated with a custom designed Lithium Niobate Electro-Optic (EO) modulator located in the target area (i.e., an area exposed to, for example, 2,000,000 V/m or 1000 A/m). The target area may be separated from the dosimetric or metering component of the system by a length of optical fiber allowing for the monitor to be located either very close or at a stand-off distance from the target detection region. Display and analysis components of the sensor system may be separated as needed to assure safety of the operators, and a reduction in RF dosage as well as protection of equipment such as electronic displays.

A fractal antenna offers tunable wideband operations in a very compact size. Depending on the iterative pattern of the fractal and the materials used to create the antenna, the antenna may be tuned to meet the goals of an ultra wide band detection component potentially with the ability to capture from 3 KHz to 100 GHz with a single device. Fractal antennas may also be tuned to provide minimum absorption of EM-field energy and have been used as cloaking devices. This may accommodate the requirement that the sensor only minimally perturb the field to be measured. Furthermore, adding additional fractal shielding outside the sensor may allow the sensor to be scaled to enormously high electrical and magnetic fields.

The sensor system may include a capacitive EO crystal that may be a unitary component with the antenna, and effectively replaces a coaxial cable that would normally connect to the antenna element. This allows sensitive electronic processing and display components to be isolated from the target region. The EO modulator acts as a phase modulator to light in response to an Electromagnetic Field (EMF) across the faces of the EO crystal. Lithium Niobate may withstand electric fields of 20 MV/m. In addition, Z-cut and X-cut LN modulators may be constructed to demonstrate high optical bandwidth and a low drive voltage across the frequency range from 1 to 100 GHz. There are challenges with extending the working range of EO modulators to 100 GHz. These challenges range arising from the difficulty coupling RF-electrical modulation to the crystal. At these high frequencies the crystal geometry and the electrode geometry become very important. The simple capacitive coatings used on kHz and MHz EO modulators become completely ineffective at high frequencies (>10 GHz). One approach is to carefully design the electrodes and crystal geometries using microwave antenna theory. Again, the combined analysis of the crystal and antenna as a single element becomes important.

An antenna may be used to couple electromagnetic waves to electronics that processes information contained in the electromagnetic wave. The antenna (e.g., a dipole antenna) produces an Electro Motive Force (EMF) across the antenna terminal that is related to the magnitude of the electric field. The relationship between electric field strength and EMF may be approximated by: Vmax=√2aE where Vmax=EMF, a=length of the edge of the antenna and E is the magnitude of the electric field. Antennas are also used to couple magnetic fields to electronics. A loop antenna, for example, may be used to measure the magnetic field by creating an EMF across the antenna terminals.

The simplest kind of EOM comprises a Crystal such as, for example, a Lithium niobate, whose refractive index is a function of the strength of the local electric field. If lithium niobate is exposed to an electric field, light may travel more slowly through it. But the phase of the light leaving the crystal may be directly proportional to the length of time it took that light to pass through it. Therefore, the phase of the laser light exiting an EOM may be controlled by changing the electric field in the crystal.

The sensor (e.g., fractal antenna and EO crystal) may be connected to processing equipment outside the target area by a fiber optic cable. The processing equipment continuously interrogates the EO modulator with a laser signal and incorporates an interferometer to demodulate the phase information encoded by the EO modulator. Two levels of instrumentation may be utilized to process the signals from the sensor. A peak detector that measures the presence and energy content of an impulse event and a peak analyzer that is able to record time-dependent profile of the impulse event to provide analysis such as, for example, rise time, fall time or details of the impulse envelope.

A single-shot version of an auto-correlator based on the Second Harmonic Generation (SHG) Frequency Resolved Optical Gate (FROG) technique called GRENOUILLE may be used to demonstrate the sensor. A 2D-camera may be used for collecting data which may be presented at a rate of less than 1 Hz. However, the product may incorporate a 1D high speed array capable of collecting data at a rate of 160 MHz. Alternatively, a system may be provided that may collect femtosecond-scale wave forms as fast as 160 million times a second. The GRENOUILLE will collect pulse information for pulses 100 MHz<f<100 GHz while lower frequency pulse data may be measured with a high-speed photodetector and a standard high-speed A/D converter.

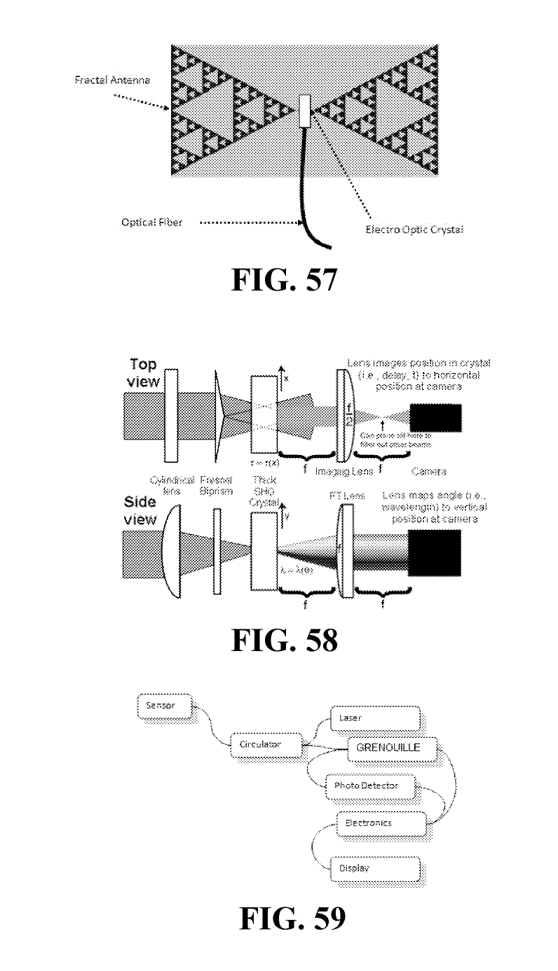

With reference to FIGS. 57-59, a schematic representation of the sensor combines a wide-band, compact fractal antenna with an electro-optic crystal that provide a phase modulation on an optical input based on detection of an EM pulse. A schematic representation of the Second Harmonic Generation (SHG) GRENOUILLE. The pulse analyzer utilizes a GRENOUILLE to analyze the pulse shape that is processed by electronics and displayed (scalable to femto-second pulses).

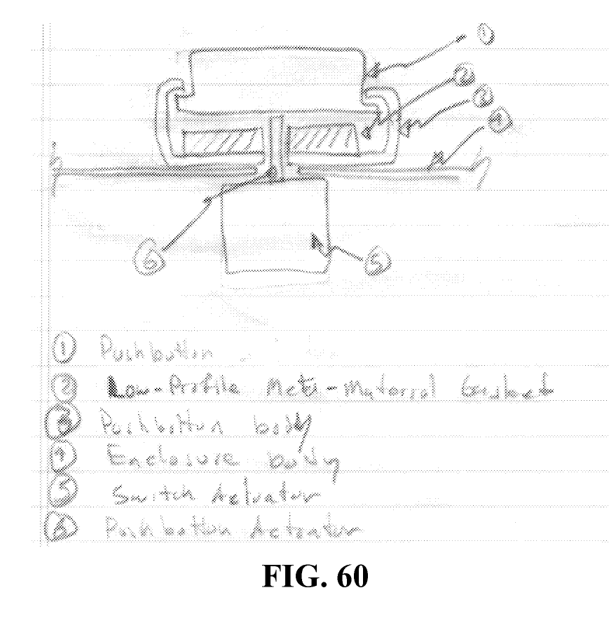

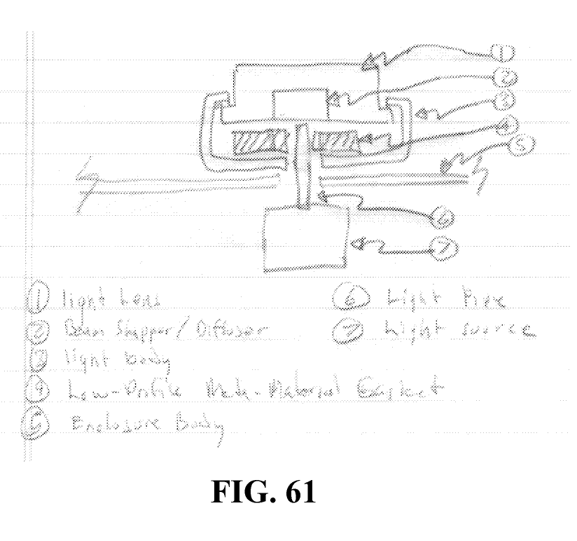

Referring now to FIG. 60, an exemplary embodiment of an electromagnetic protected industrial pushbutton system is illustrated. The pushbutton includes elements that are designed to protect against radiated and conducted EMP from an outside of an enclosure to an inside of the enclosure. The pushbutton system includes a pushbutton, a low-profile meta-material gasket, a pushbutton housing, a switch actuator, and a pushbutton actuator.

With reference to FIG. 61, an exemplary embodiment of an electromagnetic protected industrial panel light system is illustrated. The panel light includes elements designed to protect from radiated and conducted EMP from an outside of an enclosure to an inside of the enclosure. The panel light system includes a light lens, a beam shipper or beam diffuser, a light housing, a low-profile meta-material gasket, an enclosure body, a light pipe, and a light source.

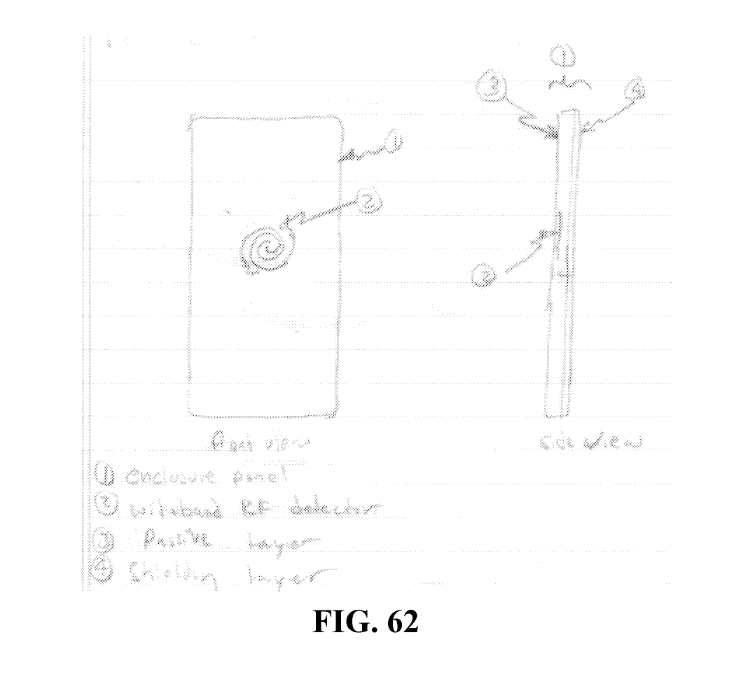

Referring now to FIG. 62, an exemplary embodiment of an electromagnetic shielded panel with integrated sensor system is provided. The system may be used with an EMP-shielded enclosure that contains an integral sensor that is capable of detecting EMP. The system includes a wideband RF detector and an enclosure panel. The enclosure panel includes a passive layer and a shielding layer.

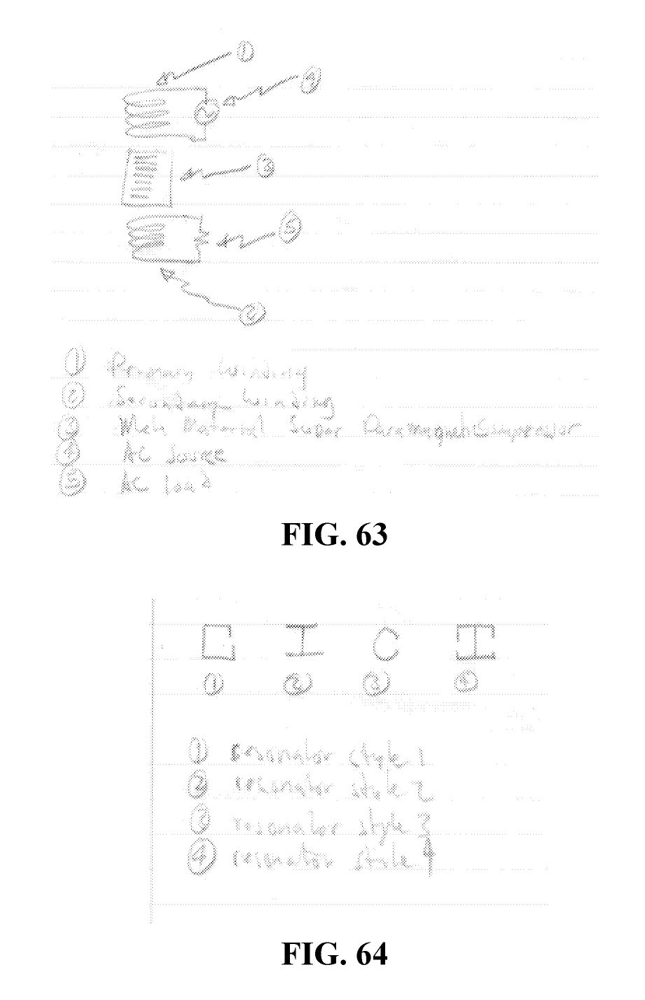

With reference to FIG. 63, an exemplary embodiment of a protected narrow-band power transformer is illustrated. The transformer includes a different transformer core. A typical transformer core may be a layered metallic or composite soft magnetic material. The current exemplary embodiment of the transformer includes a transformer core made of a meta-material. The meta-material may be a narrow-band device that may contain configurable refractive index materials. These configurable refractive index materials may be configured to operate as super-paramagnetic materials that provide higher efficiency and other operating characteristics that may not be realized using conventional magnetic materials. The transformer includes a primary winding, a secondary winding, a meta-material super-paramagnetic compressor, an AC source, and an AC load. Referring now to FIG. 64, a plurality of resonator styles are illustrated that may be assembled together to form an advanced transformer core.

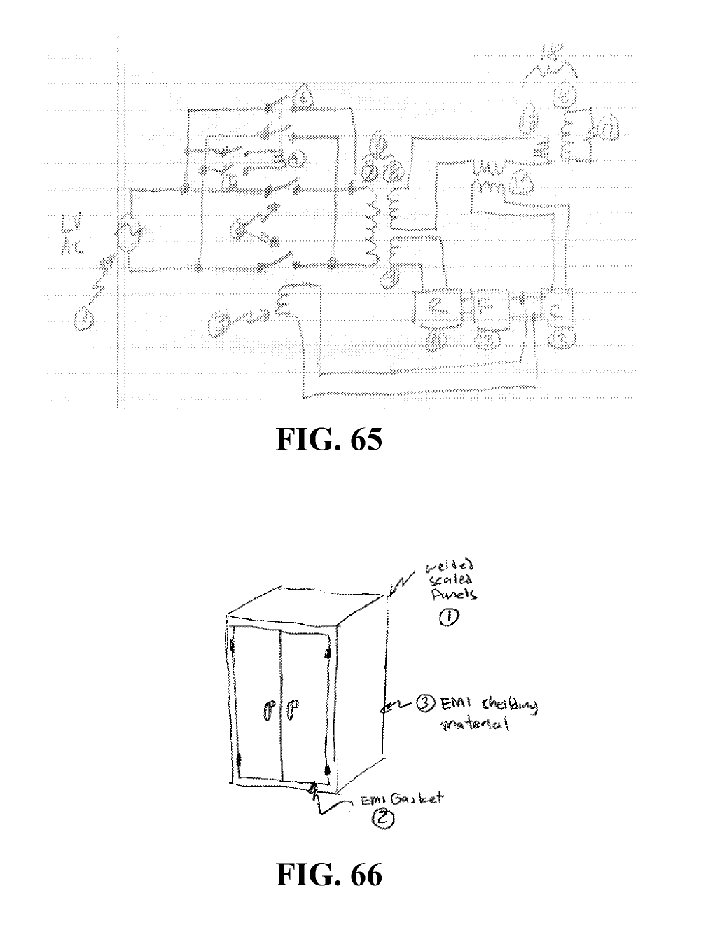

With reference to FIG. 65, an exemplary embodiment of a high voltage source is illustrated. The high voltage source is electromagnetic protected and PD-free, and is based on a saturable transformer. Conventional high voltage supplies contain mechanical variable transformers or inverter circuits that are known to cause partial discharge in the output. This partial discharge is undesirable when making precise measurements using the high voltage source. The exemplary embodiment of the high voltage source includes a power supply control comprised of: an AC source 1 that may be 120 VAC 60 Hz, 240 VAC 50 Hz, 230 VAC 60 Hz, 240 VAC 3 phase, or any other power source configuration, a safety relay 2 that open in the presence of a fault; a safety relay coil 3 that energizes the safety relay; a start relay coil 4 that energize the start relay; a momentary start 5 that holds current on the isolation relay long-enough for current to be completed as long as the safety relay is closed; a start relay 6 that supplies current to the isolation transformer; a primary 7 of the isolation transformer that supplies the power transformer; a power secondary 8 of the isolation transformer that supplies power to the HV section; a monitor secondary 9 of the isolation transformer that supplies monitor current to the monitor circuit; an isolation transformer 10 that contains a primary 7, a power secondary 8, and monitor secondary 9; a rectifier 11 that provides a DC output from the monitor circuit; a filter 12 that provides filtered DC from the rectifier circuit; a control circuit 13 that provides control voltage to the saturable transformer 14; a saturable transformer 14 that controls the current to the HV voltage transformer and thus provides clean control of the high voltage output; a primary 15 of the high voltage transformer; a secondary 16 of the high voltage transformer (>10 kV); a load 17 on the HV power supply; and an HV power supply 18 including the primary 15 and the secondary 16.

Referring to FIG. 66, an exemplary embodiment of a storage enclosure is illustrated. The enclosure is adapted to protect its contents against high amplitude electric and magnetic fields. Typical storage enclosures are made of wood, polymer and/or metallic materials. The EMP protected storage enclosure may include EMI/EMP shielded material 3 that makes up the storage enclosure, welded seams 1 if the enclosure is metallic or sealed composite panels 1 if not metal, and EMI/EMP gasket seals 2 at every opening.

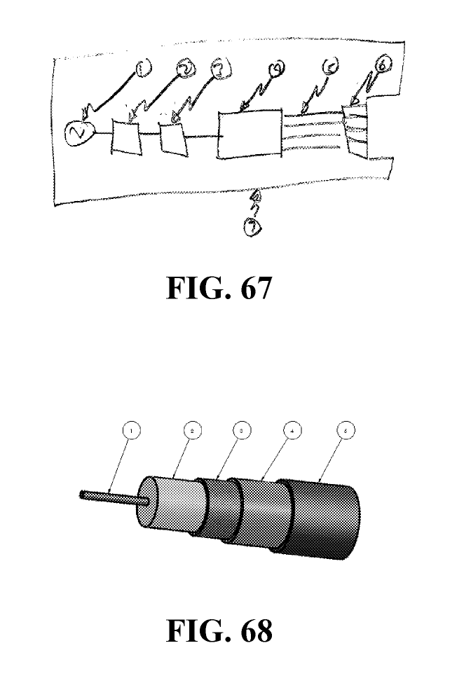

With reference to FIG. 67, an exemplary embodiment of an Ethernet system is illustrated. The Ethernet system may be included in an EMP-protected enclosure. The system provides protection to internal components of the enclosure from EMP due to either radiated or transmitted EMP. The Ethernet system includes a power source 1 for the system, a surge protector 2 capable of protecting from E1, E2 and E3 pulses, a filter 3 capable of providing EMP free power, a network electronics device 4, a cable harness 5 from the network electronics device 4, EMP-protected Ethernet connectors 6 that contain a geometry that protects from conducted and radiated EMP, and sealed shielded enclosure 7 that protects contents from EMP.

Referring now to FIG. 68, an exemplary embodiment of a cable system is illustrated. The cable system includes a shielded cable that uses coated polymers to provide strong and lightweight EMP-shielded cable. The shielding includes both conductive and magnetically permeable materials to provide broad-band shielding from electromagnetic radiation. An insulator may be voltage-dependent and act as an attenuator at high electric fields. The cable includes an inner conductor 1 made of a polymer or metal with or without conductive coating, an electric insulator or voltage-dependant (semi-conducting) electric insulator 2, and inner layer or shield 3 made of polymer with magnetic permeable material coating or metallic magnetic permeable material or meta-material, and an outer layer or shield 4 made of polymer with conductive material coating or metallic conductive material of meta-material.

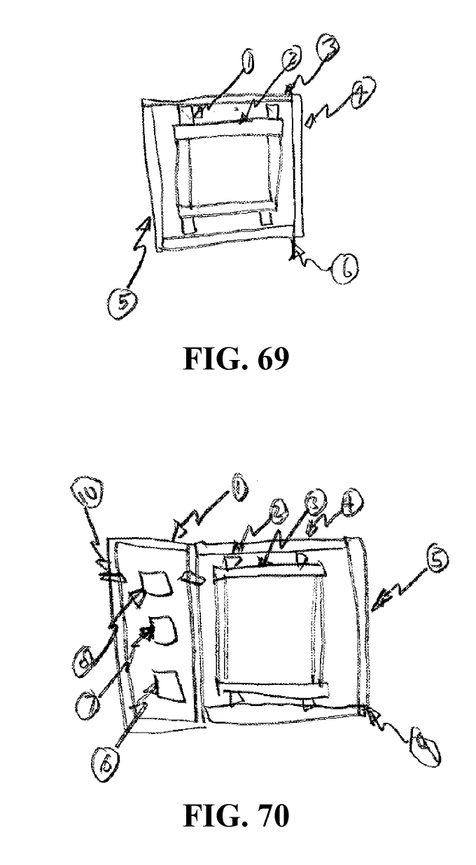

With reference to FIG. 69, an exemplary embodiment of a shipping container is illustrated. The shipping container is adapted to hold electronic devices therein and is lightweight, strong and protects the electronic devices against radiated EMP. The container includes an outer shell made from composite and/or meta-materials. The outer shell contains openings that are sealed with EMI gaskets or low-profile meta-material gasket material that exhibits super diamagnetic properties. The shipping container may include a shock-mounted frame for holding sensitive electronic devices. The enclosure protects the sensitive electronic devices from physical and electromagnetic shock. In the illustrated exemplary embodiment, the shipping container includes shock mounts 1, a frame 2 for holding electronic devices, an outer protective shell 3 that serves to protect from physical and electromagnetic shock, and a removable cover 4 to provide access to the electronic devices. Openings in the container may be sealed with gasket of meta-material super diamagnetic materials.

Referring to FIG. 70, another exemplary embodiment of a shipping container is illustrated. The shipping container is adapted to hold electronic devices therein and is lightweight, strong and protects the electronic devices against radiated EMP and conducted EMP while the electronic contents are in operation. The container includes an outer shell made from composite and/or meta-materials. The outer shell contains openings that are sealed with EMI gaskets or low-profile meta-material gaskets material that exhibit super diamagnetic properties. The shipping container includes a shock-mounted frame for holding sensitive electronic devices. The container protects the sensitive electronic devices from physical and electromagnetic shock. The enclosure also contains a shielded component that facilitates power transfer, thermal management and communication in a way that protects the contents of the enclosure from conducted and radiated EMP. This is accomplished by using feed through devices that protect the electronics from radiated and conducted EMP. IN the illustrated exemplary embodiment, the shipping container includes a shielded enclosure 1 for containing power, thermal management and communication components, a shock mount 2 to support sensitive electronics and provide shock absorbing characteristics, a frame 3 to hold sensitive electronics, an outer shell 4 to protect sensitive electronics from physical and electromagnetic shock, a removable cover 5 that allows access to sensitive electronics within the container, the opening of the cover is protected with EMI/EMP gasket or super diamagnetic materials, a power source 6 protected from radiated and conducted EMI/EMP, a thermal management system 7 that is protected from conducted and radiated EMI/EMP, a communication system 8 that is protected from conducted and radiated EMI/EMP, one or more gaskets 9 or super diamagnetic material members 9 for sealing openings in the container.

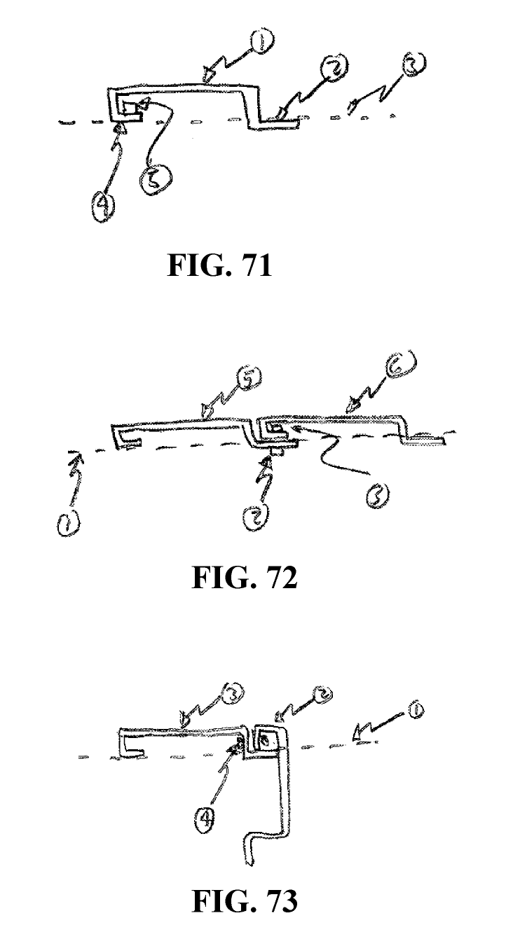

Referring now to FIGS. 71-74, an exemplary EMP/EMI protected test room or enclosure is illustrated. The room may be modular and may be made of metallic materials. The room is constructed of modular components and features both electronic screening and machine guarding. The room may also contain special provisions for power transmission, thermal control, communication and pneumatic control while maintaining protection from conducted and radiated EMI/EMP. The walls of the room have a special interlocking design that eliminates the need for gaskets or special tools to assemble. In some exemplary embodiments, the room may be assembled by a single person in only a few hours with a single tool such as, for example, a hex key wrench.

With reference to FIG. 71, the room includes side panels including a number of features that make these panels usable for walls, a ceiling, or a floor. Each panel may include a metallic shielding material 1, a flange or bend 2 that is an outward bend that falls below reference datum 3, a flange or bend 4 that is an inward bend that is above reference datum 3, and a blind nut 5 used to fasten panels together.

Referring now to FIG. 72, a flat span of wall may be created by connecting two panels together. This configuration includes a reference datum 1, a fastener 2, a blind nut 3, a first panel 5, and a second panel 6.

With reference to FIG. 73, a corner of wall may be created by connecting two panels together. This configuration includes a reference datum 1, a first panel 2, a second panel 3, and a fastener/bolt/blind nut 4.

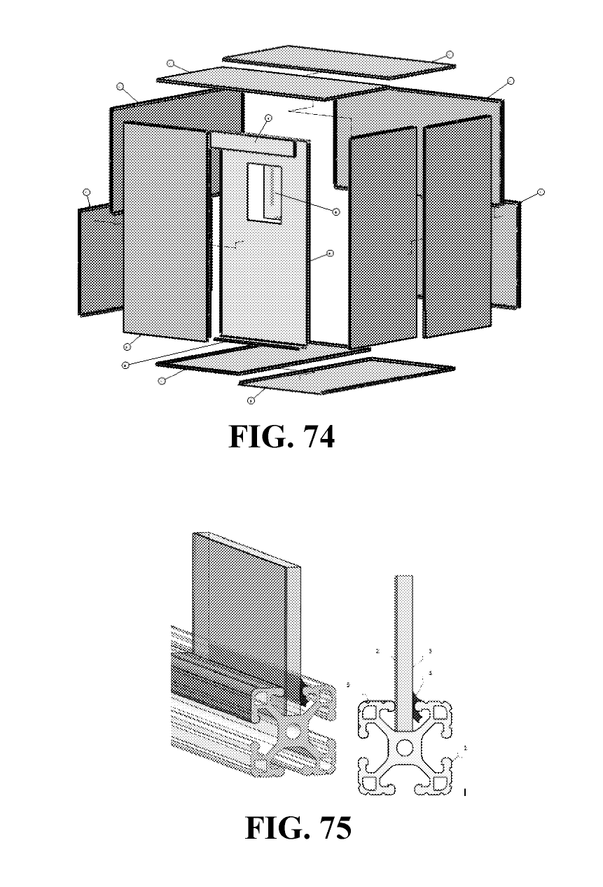

Referring to FIG. 74, the panels may be assembled to complete an enclosure. Each panel may have a similar periphery comprised of two sides with the first bend style or first flange and two sides with the second bend style or second flange.

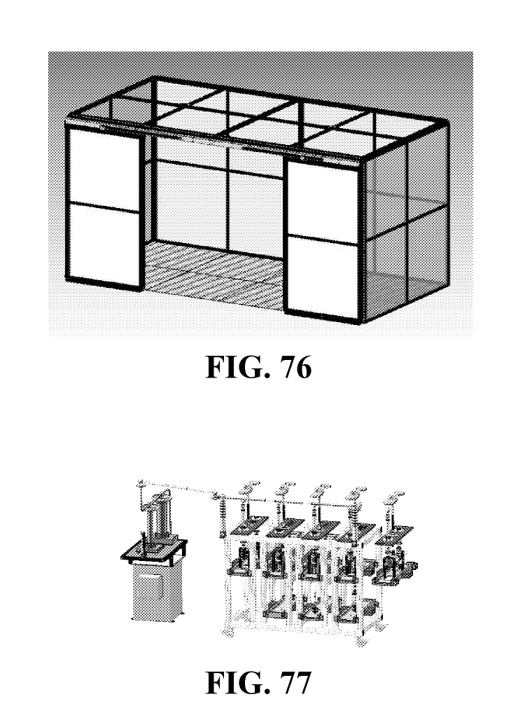

With reference to FIGS. 75 and 76, an exemplary embodiment of a modular screened room or structure is illustrated. The modular screened room may serve as a Faraday cage. The modular screen structure is constructed of modular components and features both electronic screening, machine guarding and visibility of work area. The structure also contains special provisions for power transmission, thermal control, communication and pneumatic control while maintaining protection from conducted and radiated EMI/EMP.

The modular screened structure may include a modular industrial frame 1, screen material 2 (e.g., copper, nickel, etc.), one or more polymer protective windows 3, one or more gaskets 4, conductive plating, tape, or coating 5 (e.g., copper, nickel, etc.), and a pneumatic sliding door.

In some exemplary embodiments, a 2D imaging device is provided. The 2D imaging device may include a component pneumatic rotating motor with goniometer that provides a scanning function in the first axis, a component pneumatic rotating motor with goniometer that provides a scanning function in the second axis, a component optical waveguide device that acts as a source of electromagnetic radiation from a remote source, a component optical waveguide device that acts as a conduit to relay a synchronization reference signal to a remote sensor, a component screen with a coating that provides a persistence of illumination for some time longer that the exposure time, and a remote control device that identifies the synchronization of the axis 1 goniometer and axis 2 goniometer and provides a raster signal resulting in a 2-dimensional image.

In other exemplary embodiments, a computer keyboard device is provided that does not include any electronics components within the keyboard itself. Rather, the interface contains a fiber-optic source. The fiber-optic source is introduced into the keyboard enclosure. The fiber passes by an array of keys. Any activating of the key introduces a change in the transmission characteristics of the fiber. The result is a sequence encoded onto the fiber optic transmission. The encoded sequence exits the keyboard. A protected electronic drive system that is housed in an EMP enclosure decodes sequence and identifies the keys.

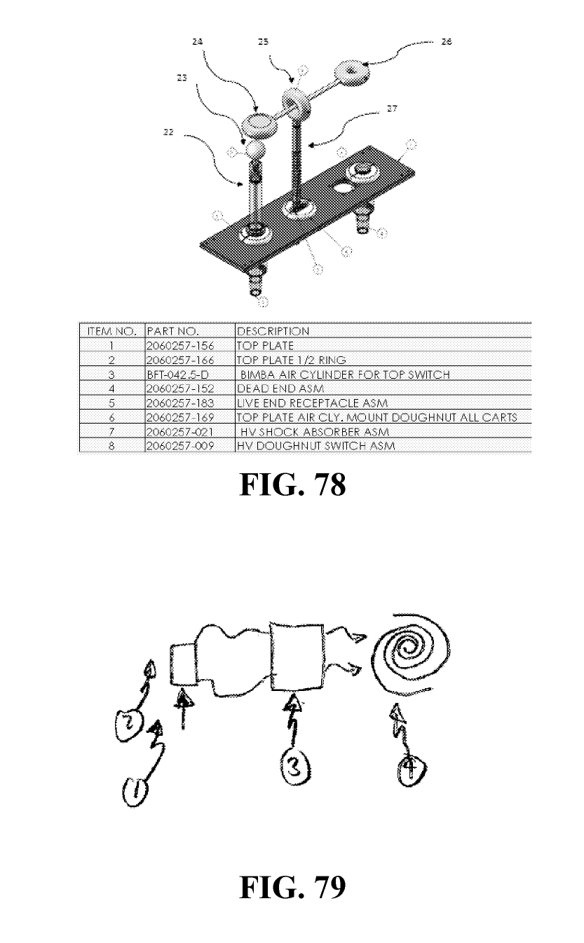

With reference to FIGS. 77 and 78, an exemplary embodiment of an air-operated switch is illustrated. The switch is partial discharge free and allows applications that do not require submersing the switch in transformer oil. Furthermore, the switch operates partial discharge levels below 1 pC. An exemplary high voltage switch application may be an automated test system. Exemplary high voltage switch components may include a load insulator 22, a load contact ball 23, a load switch contact 24, a switch pivot 25, a source contact toroid 26, and a switch standoff insulator 27.

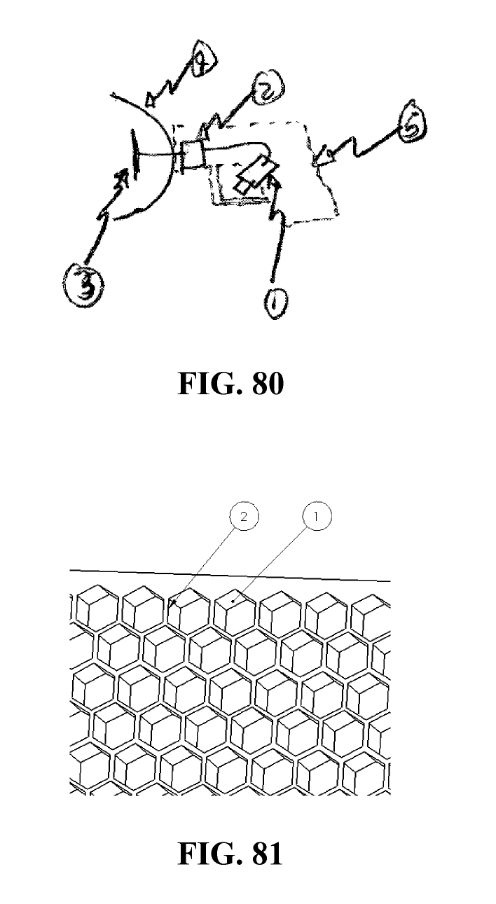

Referring to FIGS. 79 and 80, an exemplary embodiment of a generator is illustrated. The generator may be compact and protect against EMP. The generator includes a piezoelectric crystal that is mechanically perturbed in order to create a high voltage (e.g., greater than 10,000 volts) impulse. The generator may include a mechanical forcing device 1 for modulating a piezoelectric crystal, the piezoelectric crystal 2, an impedance matching network 3 to optimize power transfer between piezoelectric crystal and an antenna, and the ultrawideband antenna 4. An exemplary physical layout of the generator is illustrated in FIG. 80 and may include a piezoelectric modulator 1 with hand-operated trigger, an impedance matching device 2, ultrawideband antenna 3, a passive antenna element 4, and an ergonomic package 5.

In another exemplary embodiment, the impedance matching device may be a transmission line. A power level of this compact device may be increased dramatically by replacing passive transmission line with a charged transmission line. The concept of a charged transmission line used to generate high impulse voltages may also be referred to as a Blumlein transmission line. The Blumlein transmission acts at the pulse amplifier and the piezoelectric crystal is used as a trigger/switch to fire the Blumlein transmission line. The Blumlein transmission line would enable the device to greatly increase the power contained in each pulse generated by the system. For example, a compact high voltage DC source (e.g., 25 kV, 30 kV, 45 kV, etc.) may be used to charge the Blumlein transmission line and drive a 50 ohm load. At 25 kV this would result in a current of 500 Amperes released in a few nanoseconds. A voltage of 25 kV at 500 ampere results in a peak power in the millions of watts.

In a further exemplary embodiment, the Blumlein transmission line device may be configured to give multiple pulses from a single trigger. The device may be configured to give these multiple pulses in a predefined sequence. One possible predefined sequence is a string of pulses that produces a burst in any of the following frequencies by way of example:

Frequency (MHz)
806-824 and 851-869
824-849 and 869-894
1850-1910 and 1930-1990
698-806
1392-1395 and 1432-1435
1710-1755 and 2110-2155
2496-2690

In still another exemplary embodiment, the compact EMP generator may be used to destroy triggers in an Improvised Explosive Device (IED). The compact EMP device could be tuned to the trigger frequency of the IED and used to destroy the electronic receiver thereby disabling the IED.

In some exemplary embodiments, an enclosure is provided and includes a body having two or more mating components and a peripheral area for mating engagement to ensure a relatively sealed relationship when the components are closed. An electronically conductive and magnetically permeable liner material conformingly fits in a cavity formed by the two mating components. The peripheral edge of the liner is arranged for location in the peripheral area between the two mating components. The enclosure, when the mating components are closed, will maintain sufficiently high shielding effectiveness to protect electronic components stored within.

In other exemplary embodiments, a woven material is provided. A plurality of fibers coated with mixtures of electronically conducting and/or magnetically permeable materials are provided and the fibers may be coated in repeating pattern of electronically conducting and/or magnetically permeable materials. The patterned fibers may be woven into the woven material or cloth with repeating patterns of electronically conductive or magnetically permeable materials. The patterns may result in electromagnetically resonant structures that perturb an applied electromagnetic field.

In further exemplary embodiments, a configurable composition material is provided. A plurality of fibers coated with mixtures of electronically conducting or magnetically permeable materials are provided and the fibers may be coated in repeating pattern of electronically conducting and/or magnetically permeable materials. The patterned fibers may be embedded into a composite matrix with repeating patterns of electronically conductive and/or magnetically permeable materials along with non-conductive binder. The patterns may result in electromagnetically resonant structures that perturb an applied electromagnetic field.

In still other exemplary embodiments, a 3D configurable material or structure is provided. The structure includes electronically conductive an/or magnetically permeable materials. The structure may be created by positioning successive layers in a repeating pattern of electronically conducting and/or magnetically permeable materials. The patterns may result in electromagnetically resonant structures that perturb an applied electromagnetic field.

With reference to FIG. 81, an exemplary embodiment of a composite shield or member is illustrated. The composite shield comprises a patterned array of waveguides composed of dielectric and metallic components. The dielectric (1) fills the waveguides (2) and thus forms an impermeable skin that may be used as a panel. The dielectric may be selected to be a desired dielectric in a wavelength range that is to be shielded and also transparent in the visible, infrared or ultraviolet so that these wavelengths may pass through.

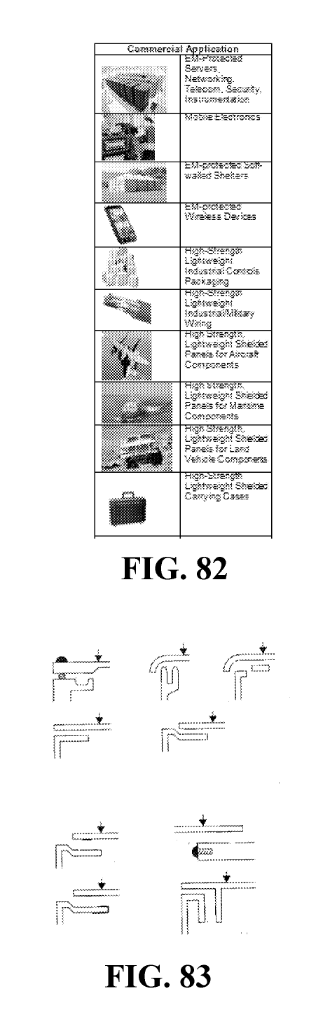

Referring to FIG. 82, exemplary applications in which composite panels may be utilized to provide electromagnetic protection are illustrated. These exemplary applications are not intended to be limiting. Rather, composite panels may be used on a wide variety of other applications and all of such applications are intended to be within the spirit and scope of the present invention. Dielectric/Metallic composite panels may be used to protect Information Technology (IT) and data center equipment. Current IT equipment is often made of non-protected composites and the additional benefit of protection would add value to the IT equipment. Mobile electronics such as, for example, military and field-able computers would benefit from electromagnetic protection in the field where a protected building is not available. High strength, lightweight panels would be useful in protecting aircraft, maritime vehicles, and Land vehicles from the EMP.

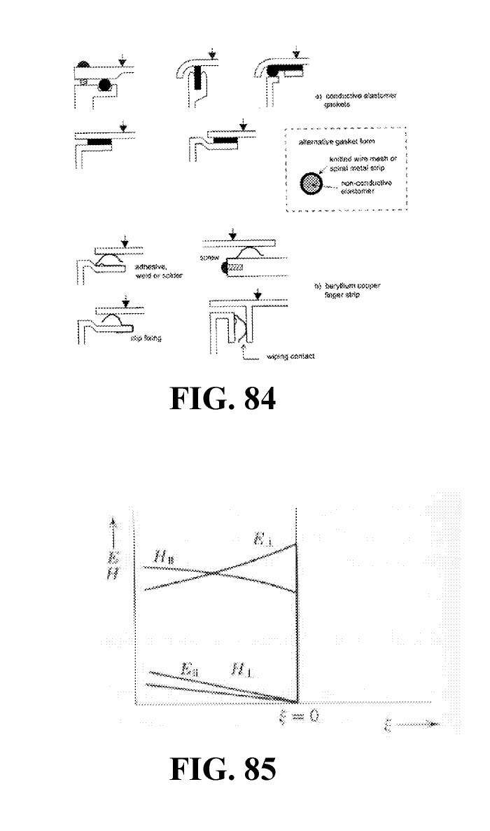

With reference to FIG. 83, gaps may be provided when enclosure panels are mated, coupled together, or otherwise positioned adjacent one another. Such gaps may not be intentional, but nevertheless are present. When panels are mated, coupled together; or otherwise positioned adjacent each other, the resulting gaps between the panels form an antenna that radiates electromagnetic energy from the outside of the enclosure to the inside of the enclosure. With reference to FIG. 84, EMI gaskets may be used to electrically seal the gaps in an enclosure. Electromagnetic radiation leaking through the gaps in an enclosure may be reduced by positioning EMI gaskets in the gaps. The design paradigm is based on deriving a mechanical design and using a mechanical solution to solve an electrical problem. Typical EMI gaskets give about a 20 db shielding effectiveness. The enclosures using EMI gaskets require special handling to make sure the correct pressure is applied and that the gaskets are properly aligned. If improper gasket handling results in a gap in the enclosure then this gap may act like and antenna and transmit electromagnetic radiation through the enclosure.

Referring to FIG. 85, a graph is illustrated that represents electric and magnetic fields near the surface of a conductor. Charges inside a perfect conductor are assumed to be so mobile that they move instantly in response to the charges in the fields, no matter how rapid, and always produce the correct surface-charge density. Similarly, for time-varying magnetic fields, surface charges move in response to the tangential magnetic field to always produce a correct surface current. As a result, the electric field normal to the surface of a conductor is related to the surface charge and the electric field tangential to the surface is zero near the surface of the conductor. Similarly, magnetic field tangential to the conductor is related to the surface current and the magnetic field normal to the surface of the conductor is zero near the surface of the conductor.

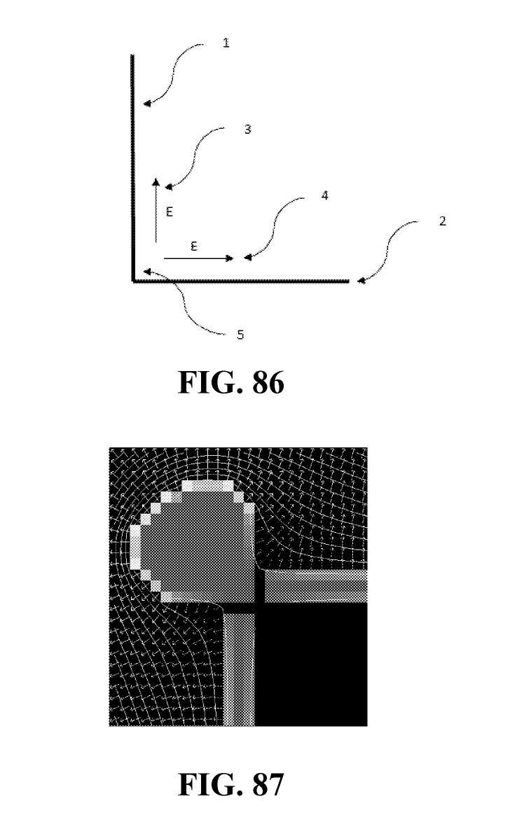

With reference to FIG. 86, conditions of Maxwell's equations are illustrated. Such conditions require the electric field to be zero at the infinitesimal corner between two perpendicular perfect conductors. Maxwell's equations establish that the parallel component of the electric field above a perfect conductor is zero. The perpendicular electric field above a perfect conductor may be non-zero. Due to the geometric relationship of the conducting surfaces of an inside corner between two conducting sheets that the perpendicular electric field (4) for the first conduction surface (1) is parallel to the second conducting surface (2). Likewise the perpendicular electric field (3) for the second conducting surface (2) is parallel to the first conducting surface (1). Thus, the electric field is always zero infinitesimally close to the inside corner (5) formed by two perfect conductors. However, in real conductors, there may be a small component of the electric field parallel to the surface of the conductor. Thus, the electric field infinitesimally close to the inside corner is very small but may not be exactly zero.

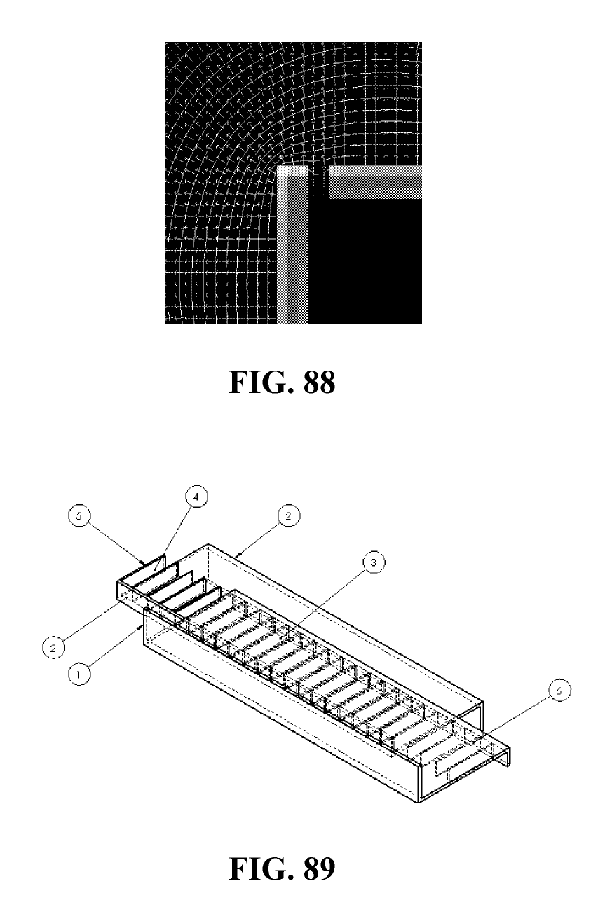

Referring now to FIG. 87, an exemplary electric field and electrical potential plot near a gap at an inside corner is illustrated. FIG. 88 illustrates an exemplary electric field and electrical potential plot near a gap at an outside corner with the electric field in the gap near the outside corner being non-zero. Using inside corners reduces the electric field, reduces the need for shielding and reduces the opportunity for failure due to manufacturing defects or improper closing of an enclosure. FIG. 87 illustrates an exemplary method to use inside corners at locations where side panels of an enclosure meet. FIG. 88 illustrates the electric field penetrating an enclosure where two panels meet when inside corners are not utilized. The enclosure of FIG. 87 takes advantage of the zero-electric field at the apex of an inside corner.

With reference to FIG. 89, an exemplary embodiment of two structured components is illustrated and the matting between the two components forms waveguides along the intersection of the components. The first side (1) of an enclosure mates to enclosure component (2). Each enclosure component contains geometric structures formed by walls (5) and (6) that, when the wall (6) slides together into wall (5), a rectangular waveguide (3) is formed. Thus, rather than forming an antenna at the interface, the components form a waveguide. Whereas antennas act to radiate electrical energy from inside the enclosure to outside the enclosure and vice versa, the waveguide attenuates all radiation below a specific frequency referred to as a cut-off frequency (fc).

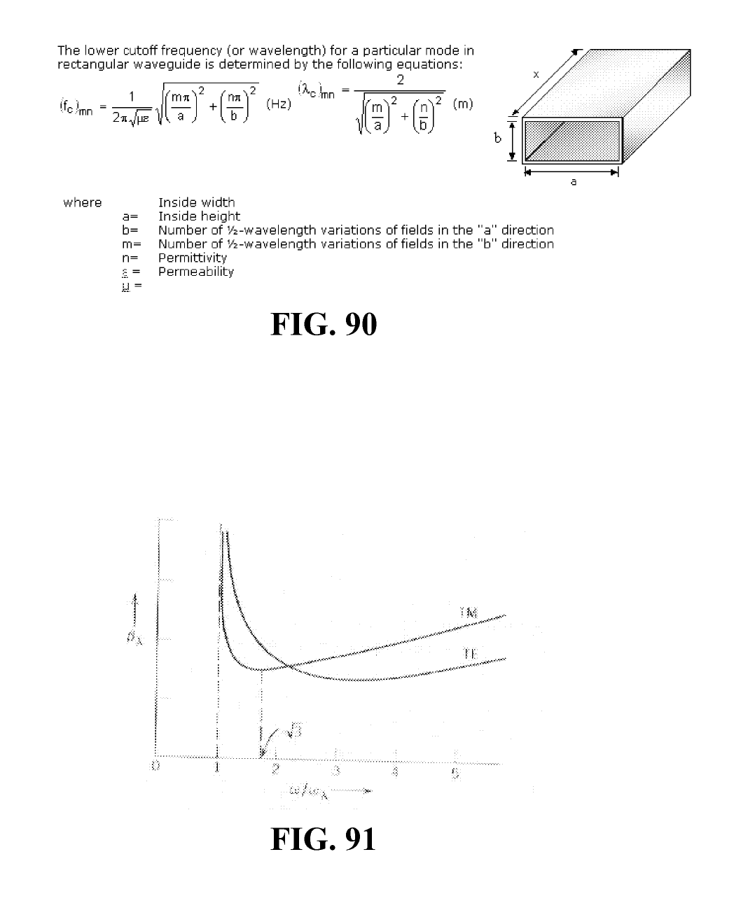

With reference to FIG. 90, an exemplary embodiment of a rectangular waveguide and associated formulas for calculating the cut-off frequency are illustrated. The cutoff frequency for a rectangular waveguide depends on the dimensions and the dielectric and magnetic properties of the interior space. Waveguides support energy flow at only certain frequencies determined by the resonant geometry of the waveguide. Below the critical frequency energy transport is highly attenuated. The attenuation is 100 db for an aperture to length ratio of 1 to 4.

Referring now to FIG. 91, an exemplary chart is illustrated that represents attenuation versus frequency for the TM and TEM modes in a waveguide which increase drastically below the cutoff frequency. The general behavior of the frequency-dependent attenuation of a waveguide is illustrated in FIG. 91. The minimum attenuation occurs at a frequency well above the cutoff. The design of the components in this disclosure is meant to operate at frequencies much less than the cutoff frequency. TM is a mode of the Transverse Magnetic wave, TE is a mode of the Transverse Electric wave, Bl is the Attenuation, w is the frequency, and wl is the cutoff frequency.

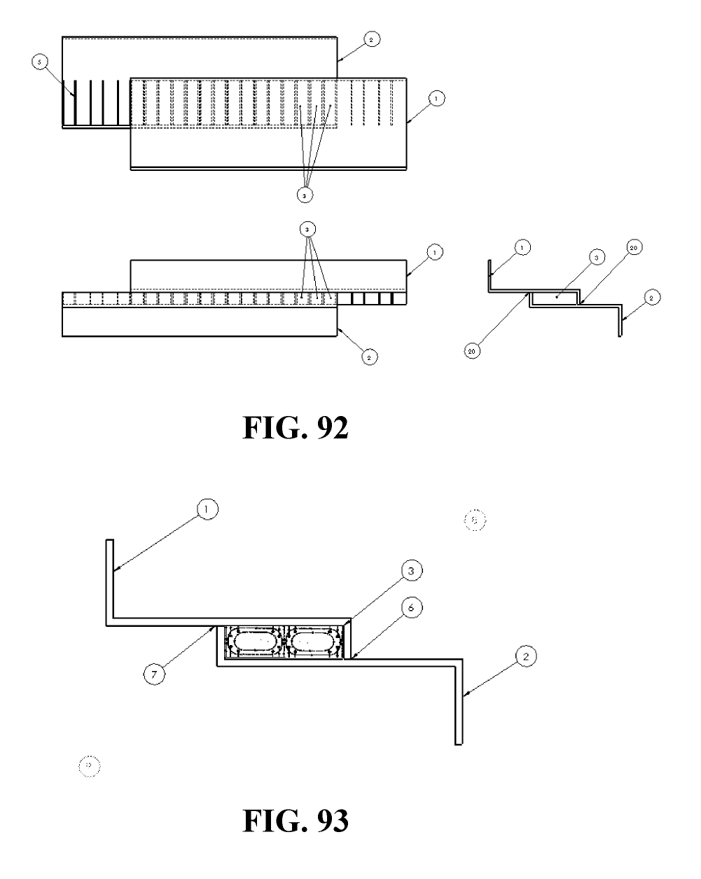

With reference to FIG. 92, two exemplary structured components are illustrated and the components meet to form waveguides at the interface between the components. Geometric structures (5) on the first enclosure component (1) and second enclosure component (2) mate to form a waveguide (3) at the interface between the two components. The gaps (20) between the first enclosure component (1) and the second enclosure component (2) are located at inside corners. Thus, by Maxwell equations, the electric field amplitude at the point will be minimal or small. The small amplitude electromagnetic field then will be transmitted into the waveguide where frequencies below the cutoff frequency are attenuated.

Referring to FIG. 93, two exemplary mating components are illustrated and form waveguides at the interface between the components. The gap (6) on the unprotected side (8) of the enclosure is located at an inside corner where the electric field from the unprotected side is minimal.

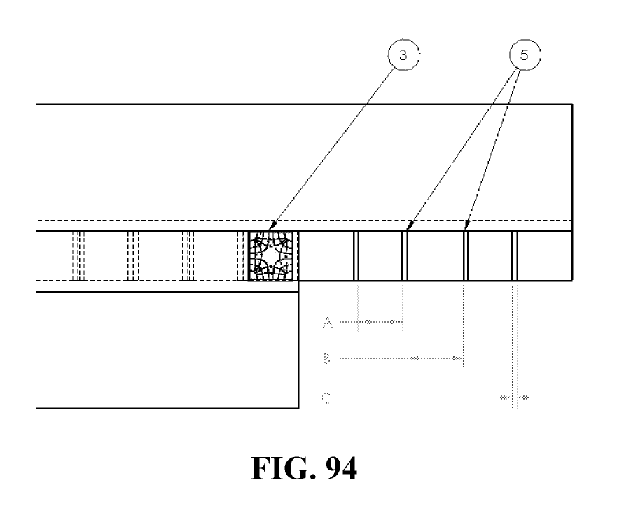

Referring now to FIG. 94, two exemplary matting components are illustrated and form waveguides at the interface between the components. Geometric structures (5) on the first enclosure component (1) and second enclosure component (2) mate to form a waveguide (3) at the interface between the two components. In one exemplary embodiment, the spacing between adjacent panels may be varied to reduce resonance that diminishes attenuation. The electric field in the corners of the waveguide is near zero and thus does not significantly affect the operation of the waveguide.

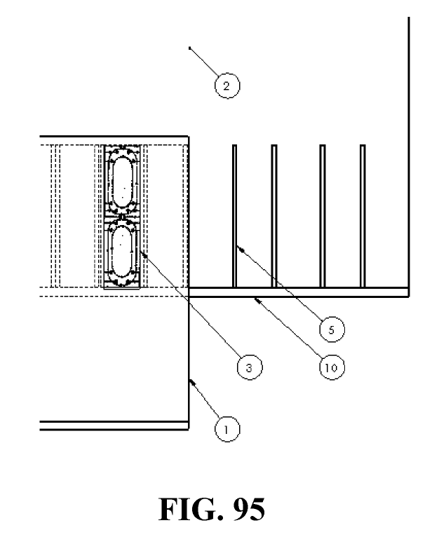

With reference to FIG. 95, two exemplary mating components are illustrated and form waveguides at the interface between the components. Geometric structures (5) on the first enclosure component (1) and second enclosure component (2) mate to form a waveguide (3) at the interface between the two components. In one exemplary embodiment, the spacing between adjacent panels may be varied to reduce resonance that diminishes attenuation. The electric field in the corners of the waveguide is near zero and thus does not significantly affect the operation of the waveguide.

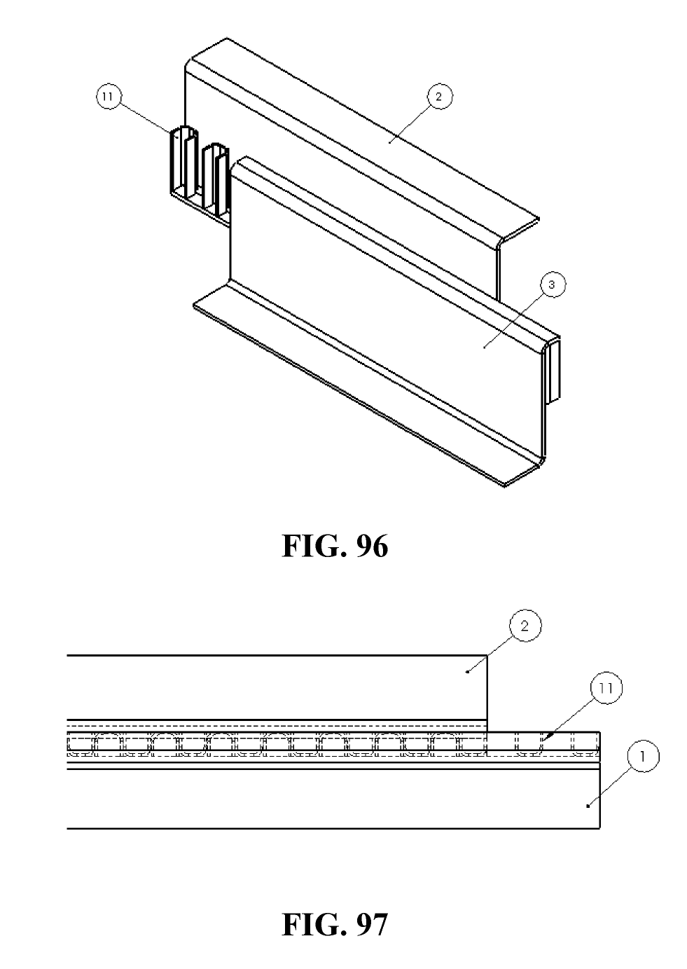

Referring to FIG. 96, two exemplary mating components are illustrated and meet to form waveguides at the interface between the components. Geometric structures (11) on the first enclosure component (1) and second enclosure component (2) mate to form a waveguide at the interface between the two components. The geometric structures may also be formed from sheet metal.

Referring now to FIG. 97, two exemplary mating components are illustrated and meet to form waveguides at the interface between the components. Geometric structures (11) on the first enclosure component (1) and second enclosure component (2) mate to form a waveguide at the interface between the two components. The geometric structures may also be formed from sheet metal.

Blade and rack-mounted servers are popular form factors for data center servers. These types of server have been used, for example, in data farms and in high performance supercomputers. In order to achieve high performance, many rack-mounted servers are clustered and connected using fiber optic interconnects. This may result in hundreds or even thousands of individual optical fibers emerging from a single server package. Adjusting traditional server I/O designs providing a rack or cabinet with a door to access optical interconnects could be problematic because such designs do not scale well to the number of fibers required and because the resulting large size of the cabinets produces excessive exposure to both coupled and conducted electromagnetic noise.

A shielding apparatus according to an embodiment as disclosed herein has includes an enclosure that comprises first and second electrically conductive sheets, spaced apart in a substantially parallel relationship, with both the first and second electrically conductive sheets being in electrical communication with a ground. A gap lies between the first and second electrically conductive sheets. Separators are attached to the electrically conductive sheets. The separators attached to one sheet interlock with the separators on the second sheet to form a cavity between each of the separators. The length of the first and second electrically conductive separators is at least four times the size of the gap, the gap and first and second electrically conductive sheets are thereby sized to prevent propagation of electromagnetic radiation above a predefined wavelength.

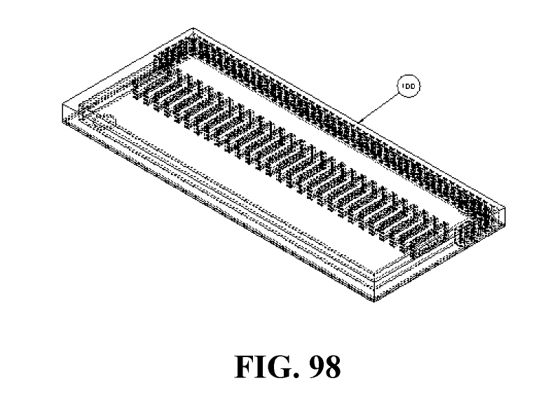

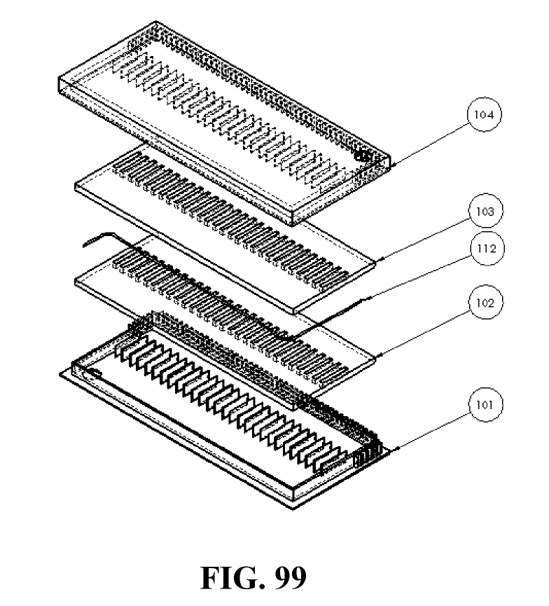

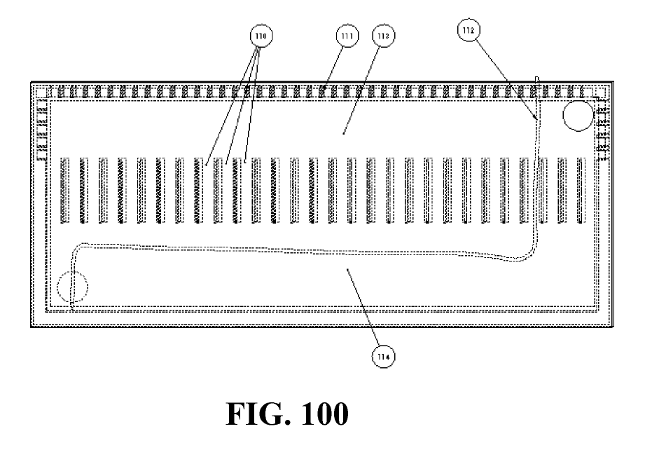

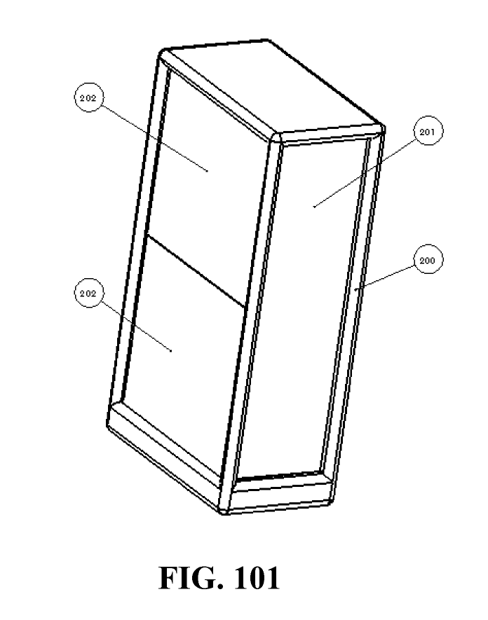

Referring now to FIGS. 98-100, an EMI/EMP protected cable management system is illustrated and includes two mating structured components meeting to form waveguides at the interface between the components. The cable management system (100) includes a first cover (104) that possesses geometric components that when interlocked with the geometric structures on the second cover (101) form waveguides. The first cover (104) and second cover (101) are made from either conductive or dielectric materials and are coated with one or more conductive coatings. A non-metallic cable (112) is sandwiched between optional locating pads (102) and (103). The locating pads (102) and (103) may be comprised of RF-absorbing foam. The locating pads (102) and (103) help to maintain the location of the cables (112) and also serve to absorb additional radiation present within cable management device. Non-conductive cable (112) passes from external or unprotected side (114) of cable management system to protected side (113) of cable management system. The cable passes through waveguide (110) that is formed by the mating of geometric components of each of the first side (104) and second side (101) of the cable management system.

With reference to FIG. 101, an exemplary EMI/EMP protected cabinet or enclosure for containing electronic devices is illustrated. The enclosure includes inside corners on the main frame and waveguide interfaces on panels and doors. The side panels, doors, and other moveable enclosure components may be protected from EMI by creating inside corners at each interface and using waveguide interfaces as described herein.

In a first exemplary embodiment, a method of producing an EMI/EMP protected enclosure for holding electronic devices is provided. The method may include, for example, building a test EMI/EMP protected enclosure according to an enclosure design, performing an acceptance testing procedure on the test EMI/EMP protected enclosure to determine if it meets an EMI/EMP protection level according to MIL STD 188 125 I, and producing a plurality of EMI/EMP protected enclosures according to the enclosure design if the test EMI/EMP protected enclosure meets the EMI/EMP protection level according to MIL STD 188 125 1. In some cases, the test EMI/EMP protected enclosure has dimensions consistent for use in a data center. For example, dimensions may be 2000 mm in height, 600 mm in width, and 1000 mm in depth. Alternative dimensions may be 2000 mm in height, 800 mm in width, and 800 mm in depth. These limitations are not intended to be limiting. Rather, any possible enclosure dimensions are possible and are intended to be within the spirit and scope of the present invention. The EMI/EMP protected enclosure may include a power input point of entry that facilitates entry of a power cable to the reduced EMI/EMP interior space from a location external to the enclosure. The enclosure may also include a fiber optic cable point of entry that facilitates entry of a fiber optic cable into the EMI/EMP protected interior space of the enclosure from a location external to the enclosure. The cable points of entry are protected from ingress of EMI/EMP energy by an EMI/EMP protected cable management device. The cooling of the EMI/EMP cabinet may be facilitated by flowing cooled air through waveguide protected ventilation opening. The ventilation opening may be connected to data center cooling by a plenum.

In another exemplary embodiment, another EMI/EMP protected enclosure is provided for holding an electronic device. The enclosure may include, for example, two interior spaces. One interior space may have a reduced EMI/EMP exposure (e.g., 20 db shielding effectiveness). The second interior space has a greater reduction in EMI/EMP exposure (e.g., 100 db shielding effectiveness). The second interior space may have one or more racks disposed therein for supporting one or more electronic devices. In some exemplary embodiments, dimensions of the enclosure may be 2000 mm in height, 600 mm in width, and 1000 mm in depth. In other exemplary embodiments, dimensions of the enclosure may be 2000 mm in height, 800 mm in width, and 800 mm in depth. These limitations are not intended to be limiting. Rather, any possible enclosure dimensions are possible and are intended to be within the spirit and scope of the present invention. The enclosure may provide an EMI/EMP protection level to the electronics devices, including servers and networking equipment, that meets an EMI/EMP protection level according to MIL STD 188125 I. In some cases, the enclosure provides an EMI/EMP protection level to the electronic device of at least 100 dB attenuation at 1 GHz. In related cases, the enclosure provides an EMI/EMP protection level to a telecommunications device of at least 80 dB attenuation at 1 GHz. The EMI/EMP protected enclosure may have a power input point of entry that facilitates entry of a power cable to the reduced EMI/EMP interior space from a location external to the enclosure. The enclosure may also include a fiber optic cable point of entry that facilitates entry of a fiber optic cable to the EMI/EMP protected interior space from a location external to the enclosure. The cable points of entry are protected from ingress of EMI/EMP energy by an EMI/EMP protected cable management device. The cooling of the reduced EMI/EMP interior space may be facilitated by flowing cooled air through waveguide protected ventilation opening. A heat exchanger may be used to cool the EMI/EMP protected interior space. The thermodynamic connections between the two interior spaces are sealed with the plumbing soldered or welded to the enclosure panel. Similarly, the enclosure may include a converter and a battery coupled with the converter. The enclosure may also include a power filter. A clean output of the power filter may be disposed within the interior space of the enclosure. A dirty input of the power filter may be disposed external to the enclosure. In some cases, the enclosure includes a front opening that may be configured to receive an electronic device there through. In some aspects, the enclosure includes a power input point of entry that facilitates entry of a power cable to the interior space from a location external to the cabinet, where the power input point of entry is disposed at a top surface of the enclosure. In some aspects, the enclosure includes a fiber optic cable point of entry that facilitates entry of one or more fiber optic cables to the interior space from a location external to the cabinet, where the fiber optic cable point of entry utilizes an EMI/EMP protected cable management system. The enclosure may also include a power cable coupled with the power input point of entry, and a fiber optic cable coupled with the fiber optic cable point of entry.

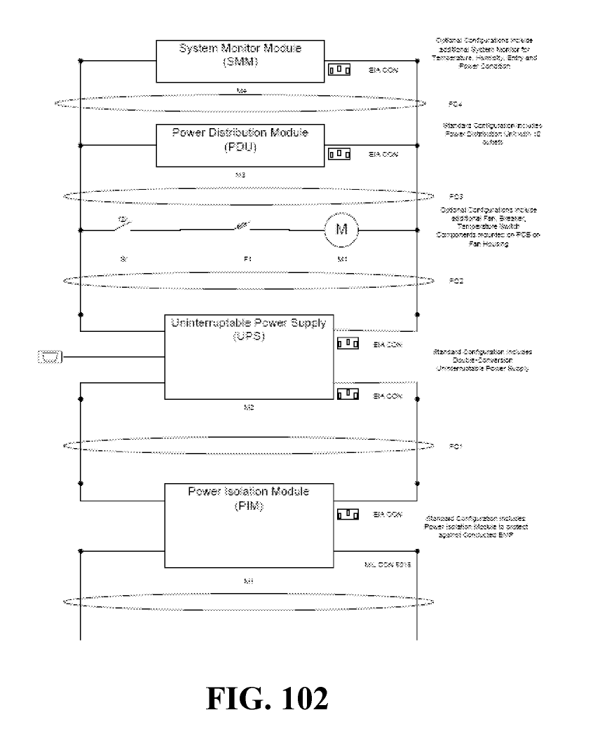

Referring to FIG. 102, an exemplary system is illustrated for active protection and control.

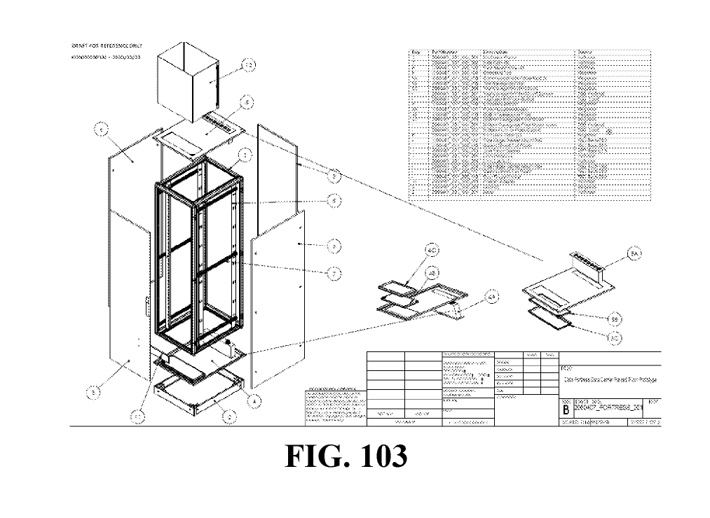

With reference to FIG. 103, another exemplary enclosure is illustrated and provides EMI/EMP protection to electronic devices within the enclosure. The enclosure includes inside corners on a main frame and waveguide interfaces on panels and doors. The enclosure may be fitted with a plenum to data center ductwork. EMI/EMP protected interfaces for power and communication may also be provided.

In some exemplary embodiments, the enclosure may use existing data center heating and cooling by incorporating waveguide feed through in the ductwork, an EMI/EMP protected power entry, and EMI/EMP protected data communication entry/cable management system. The enclosure frame (1) includes inside corner design along with waveguide features for panel and door interfaces. Side rails (7) and rack mount rails (8) allow for mounting of electronic devices such as, for example, servers, network equipment, etc. The enclosure top (5) is mounted to the frame and contains EMI/EMP protected ductwork (12) for thermal management and communication. An EMI/EMP-protected ventilation filter (5B) is secured in place with a mounting frame (5C). An EMI/EMP-protected cable management system separates internal data connections from external EMI/EMP threats. The enclosure bottom (4) is mounted to the frame and contains EMI/EMP-protected ventilation filter (4B) secured in place with a mounting frame (4C). The bottom cover also includes a sub-enclosure containing EMI/EMP-protected power isolation module. The base (2) is attached to the bottom of the entire enclosure. The enclosure includes EMI/EMP-protected side panels (6) and doors (3). The stationary electronics enclosure includes all items necessary to protect contents against radiated and conducted EMP. This stand-alone enclosure includes all components needed for server operation and EMP protection such as, but not limited to, EMP-protected power, EMP-protected communication, EMP-protected environmental control, etc.

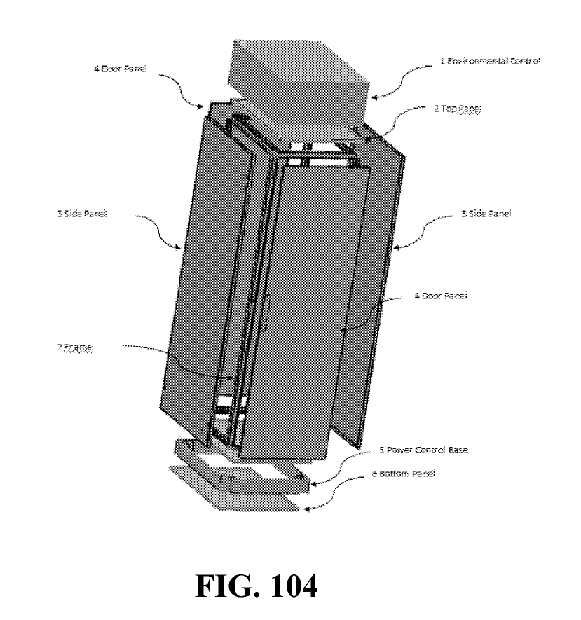

Referring now to FIG. 104, a further exemplary enclosure is illustrated and provides protection against EMI/EMP. The enclosure includes inside corners on a main frame and waveguide interfaces on panels and doors. The enclosure may be fitted with EMI/EMP-protected, self-contained thermal management system and EMI/EMP protected interfaces for power and communication. The enclosure frame (7) uses inside corner design along with waveguide features for panel and door interfaces. Side rails and rack mount rails allow for mounting of electronic devices including, but not limited to, servers, network equipment, etc. Enclosure top (2) is mounted to the frame and contains EMI/EMP-protected environmental controls (1). An EMI/EMP-protected cable management system separates internal data connections from external EMI/EMP threats. The enclosure bottom (6) is mounted to the frame. The bottom cover also includes a sub-enclosure containing an EMI/EMP-protected power isolation module.

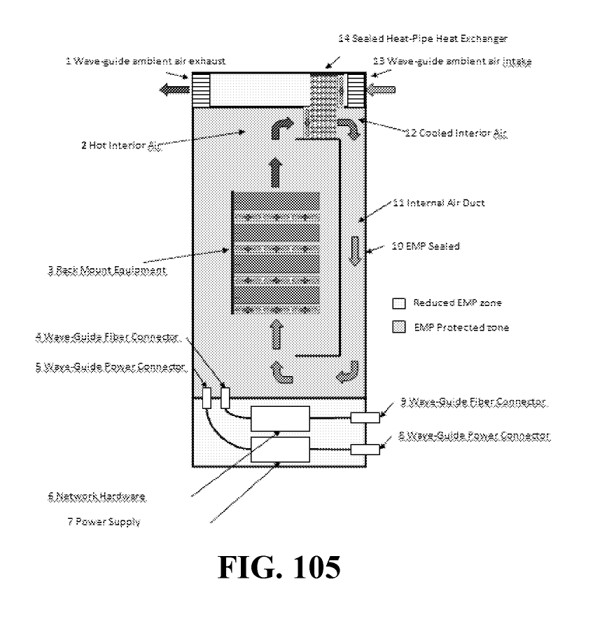

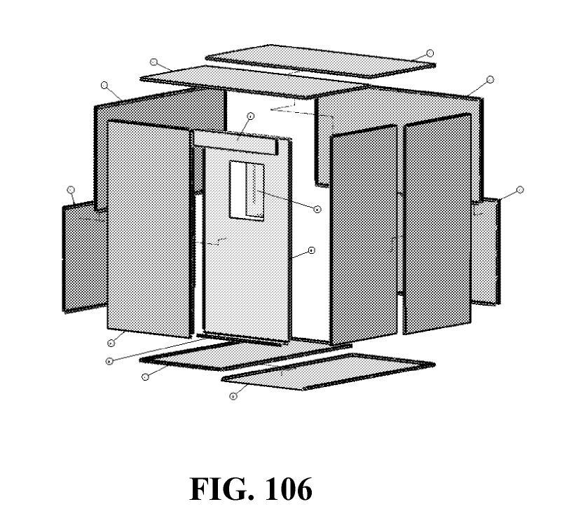

With reference to FIG. 105, still another enclosure is illustrated and provides protection against EMI/EMP. The enclosure includes inside corners on a main frame and waveguide interfaces on panels and doors. The enclosure may include an EMI/EMP-protected, self-contained thermal management system and EMI/EMP protected interfaces for power and communication.

Referring to FIG. 106, an exemplary embodiment of a room or enclosure is illustrated and protects against EMI/EMP. The room may include inside corners on a main frame and waveguide interfaces on panels and doors. Panels may be made with modular design and assembled in unique order to allow modular panel design. The room may also include an EMI/EMP-protected, self-contained thermal management system and EMI/EMP protected interfaces for power and communication.

Larger rooms or enclosures such as, for example, tents, test rooms, command and control rooms, server rooms, and small buildings may be protected by using the combination of inside corners and waveguide interfaces.

The foregoing description has been presented for purposes of illustration and description, and is not intended to be exhaustive or to limit the invention to the precise form disclosed. The descriptions were selected to explain the principles of the invention and their practical application to enable others skilled in the art to utilize the invention in various embodiments and various modifications as are suited to the particular use contemplated. Although particular constructions of the present invention have been shown and described, other alternative constructions will be apparent to those skilled in the art and are within the intended scope of the present invention.

1. An apparatus for electromagnetically isolating electronic devices from a surrounding environment and for preventing a transfer of electrical field energy and magnetic field energy between the electronic devices and the surrounding environment, the apparatus comprising:
a plurality of enclosure walls;
a connection member between the enclosure walls;
a first opening defined in one of the plurality of enclosure walls;
a second opening defined in one of the plurality of enclosure walls;
an electronic penetration passing through the first opening; and
a non-electric penetration passing through the second opening.

2. The apparatus of claim 1, wherein the plurality of enclosure walls are comprised of a composite of dielectric interposed by a patterned array of conductive materials that together act as a broad-band electromagnetically-resonant attenuator.

3. The apparatus of claim 2, wherein patterned array of conductive materials may be comprised of waveguides including length and width proportions that provide attenuation of at least 100 dB.

4. The apparatus of claim 2, wherein the dielectric is air.

5. The apparatus of claim 2, wherein the dielectric is a polymer.

6. The apparatus of claim 2, wherein the dielectric is an insulating material.

7. The apparatus of claim 1, wherein the connection member is comprised of a composite of dielectric interposed by a patterned array of conductive materials that together act as a broad-band electromagnetically-resonant attenuator.

8. The apparatus of claim 7, wherein the patterned array of conductive materials are comprised of waveguides including length and width proportions that provide attenuation of at least 20 dB.

9. The apparatus of claim 7, wherein the patterned array of conductive materials are comprised of waveguides including length and width proportions that provide attenuation of at least 100 dB.

10. The apparatus of claim 7, wherein the dielectric is air.

11. The apparatus of claim 7, wherein the dielectric is a polymer.

12. The apparatus of claim 7, wherein the dielectric is an insulating material.

13. The apparatus of claim 1, wherein the plurality of enclosure walls are geometrically arranged to attenuate an electric field.

14. The apparatus of claim 1, wherein the plurality of enclosure walls are geometrically arranged to attenuate a magnetic field.

15. The apparatus of claim 1, wherein the plurality of enclosure walls are geometrically arranged to attenuate both an electric field and a magnetic field.

16. The apparatus of claim 1, wherein the connection member has a geometric arrangement of an inside corner.

17. The apparatus of claim 1, wherein the inside corner is positioned on the enclosure at a location where edges of adjacent walls mate.

18-27. (canceled)
